(19) United States
(12) Patent Application Publication
(10) Pub. No.: US 2014/0050244 A1
(43) Pub. Date: Feb. 20, 2014

(54) SUPERLUMINESCENT DIODE

(71) Applicant: Panasonic Corporation, Osaka (JP)

(72) Inventors: Hiroshi OHNO, Osaka (JP); Kazuhiko YAMANAKA, Osaka (JP); Kenji ORITA, Osaka (JP); Shinichiro NOZAKI, Kyoto (JP)

(73) Assignee: Panasonic Corporation, Osaka (JP)

(21) Appl. No.: 14/065,519

(22) Filed: Oct. 29, 2013

Related U.S. Application Data
(63) Continuation of application No. PCT/JP2012/002539, filed on Apr. 12, 2012.

(30) Foreign Application Priority Data
May 2, 2011 (JP) 2011-103022

(51) Int. Cl. H01L 33/00

(52) U.S. Cl. CPC H01L 33/0045
USPC 372/46.01

(57) ABSTRACT

A superluminescent diode has, above a substrate, a layered portion including at least a first cladding layer, a luminescent layer, and a second cladding layer in this order, and an optical waveguide having a refractive-index guiding structure is provided in the layered portion. The optical waveguide includes: a first mesa portion formed by processing the second cladding layer into the first mesa portion having a first width; and a second mesa portion formed by processing the first cladding layer, the luminescent layer, and the second cladding layer into the second mesa portion having a second width greater than the first width.

### CROSS REFERENCE TO RELATED APPLICATIONS

This is a continuation application of PCT International Application No. PCT/JP2012/002539 filed on Apr. 12, 2012, designating the United States of America, which is based on and claims priority of Japanese Patent Application No. 2011-103022 filed on May 2, 2011. The entire disclosures of the above-identified applications, including the specifications, drawings and claims are incorporated herein by reference in their entirety.

### FIELD

The present disclosure relates to a superluminescent diode, and particularly relates to a superluminescent diode which emits light within a wavelength range of visible light from blue-violet to red.

### BACKGROUND

Recently, semiconductor light-emitting devices such as a light emitting diode (LED), a laser diode (LD), and a superluminescent diode (SLD) have been attracting attention as light sources of various electrical apparatuses.

In particular, due to both the high directivity and the low coherence, the SLD is being developed as a light source for a medical apparatus such as an optical coherence tomography (OCT) system, or, in recent years, a light source for an image display device such as a projector.

Like the LD, the SLD is a semiconductor light-emitting device including an optical waveguide, in which light generated in a recombination process of injected carriers, i.e. spontaneously emitted light, is amplified with high gain by stimulated emission while traveling toward a light output end face, and the amplified light exits from the light output end face.

On the other hand, unlike the LD, the SLD prevents formation of an optical resonator by reflection between end faces, thereby preventing Fabry-Perot mode lasing. Accordingly, in the SLD, the mode reflectivity is reduced to suppress the lasing by tilting the light output end face relative to the optical waveguide for example. Such a SLD has an incoherent property and a broad spectrum profile, like a normal light-emitting diode. In addition to this, it is possible to provide light output at a narrow angle of radiation.

Thus, the SLD differs in characteristics from the LD because the SLD does not use the oscillation phenomenon caused by resonance. Here, the characteristics of the SLD and the LD are described with reference to FIG. 20. FIG. 20 illustrates a graph showing electrical current vs. optical output characteristics for the SLD and the LD.

As shown in FIG. 20, the SLD does not have a definite lasing threshold (Ith) as shown in the LD. In a rise of the optical output, as shown in a range Ex, the SLD has the characteristics of an exponential increase in the optical output caused by light amplification.

According to the simplest model of the SLD, the optical output Po of a time when light generated in a luminescent layer propagates through the optical waveguide while being optically amplified and exits from the output end is expressed by the following equation.

P₀=A·∫₀^{L}{e^{[Γ}^{ᵥ}^{·g(J)-α}^{ᵢ}^{]·z}}·dz. [Equation 1]

Where L is the length of the optical waveguide, Γv is the vertical optical confinement factor of the optical waveguide, g(J) is the optical gain of the luminescent layer at the current density J, αi is the waveguide loss in the optical waveguide, A is the factor representing the ratio at which the spontaneously emitted light in the luminescent layer is coupled into the waveguide mode, and z is a point in the optical waveguide (0≦z≦L).

As shown in FIG. 20, in the SLD, the optical output rises exponentially. As a result, there is a problem that the optical output of the SLD rises more slowly than that of the LD and thus a larger operating current (Iop) is needed. When the SLD is used as a light source in the electrical apparatus such as a projector, higher luminescent efficiency is desired for the SLD. Accordingly, it is very important how the rising current (operating current) corresponding to the threshold current (Ith) of the LD is reduced in the SLD.

According to Equation 1, one of the ways to decrease the rising current of the SLD is to increase the spontaneously-emitted-light coupling factor A. In order to increase the spontaneously-emitted-light coupling factor A, a difference in effective refractive index Δn between the inside and the outside of the optical waveguide should be increased. This difference in refractive index Δn varies depending on the structure of the optical waveguide.

The conventional optical-waveguide structures include a shallow mesa structure and a deep mesa structure. The shallow mesa structure has a mesa portion (ridge portion) formed by shallowly digging stacked semiconductor layers, whereas the deep mesa structure has a mesa portion (ridge portion) formed by deeply digging the stacked semiconductor layers to the bottom of the luminescent layer. For example, Patent Literature (PTL) 1 or 2 discloses a semiconductor laser having a deep-mesa optical waveguide.

### CITATION LIST

### Patent Literature

[PTL 1] Japanese Unexamined Patent Application Publication No. 6-177487
[PTL 2] Japanese Unexamined Patent Application Publication No. 2002-118324

### SUMMARY

### Technical Problem

In this section, a semiconductor light-emitting device having a shallow-mesa optical waveguide and a semiconductor light-emitting device having a deep-mesa optical waveguide are described with reference to FIG. 21A and FIG. 21B, respectively. FIG. 21A illustrates a cross-sectional view of the semiconductor light-emitting device having the shallow-mesa optical waveguide. FIG. 21B illustrates a cross-sectional view of the semiconductor light-emitting device having the deep-mesa optical waveguide.

As shown in FIG. 21A, the semiconductor light-emitting device having the shallow-mesa optical waveguide 1001 includes a semiconductor layered portion in which a buffer layer 1011, an n-type lower cladding layer 1012, an n-type lower guiding layer 1013, a luminescent layer 1014, a p-type upper guiding layer 1015, and a p-type upper cladding layer 1016 are sequentially formed above a substrate 1010.

In the upper cladding layer 1016, a stripe-shaped shallow mesa portion 1031 is formed as a ridge-type optical waveguide. On the upper cladding layer 1016, a dielectric insulating layer 1017 having an opening in which a top surface of the shallow mesa portion 1031 is exposed is formed. Furthermore, a p-side electrode 1018 is formed on the top surface of the shallow mesa portion 1031 to cover the opening of the dielectric insulating layer 1017.

On the dielectric insulating layer 1017 including the p-side electrode 1018, a pad electrode 1019 electrically connected to the p-side electrode 1018 is formed. It should be noted that an n-side electrode 1020 is formed on a back surface of the substrate 1010.

On the other hand, as shown in FIG. 21B, a semiconductor light-emitting device having the deep-mesa optical waveguide 1002 also includes a semiconductor layered portion similar to that of the semiconductor light-emitting device 1001 in FIG. 21A. Unlike the semiconductor light-emitting device having the shallow-mesa optical waveguide 1001, the semiconductor light-emitting device having the deep-mesa optical waveguide 1002 has an optical waveguide in which a deep mesa portion 1032 is formed by digging the semiconductor layered portion to the lower cladding layer 1012.

In order to increase the difference in refractive index Δn of the optical waveguide, the deep-mesa optical waveguide as shown in FIG. 21B is preferred to the shallow-mesa optical waveguide as shown in FIG. 21A.

In particular, when a semiconductor laser has the optical waveguide formed as the deep mesa structure, the threshold and the parasitic capacitance can be reduced. In addition, for a curved optical waveguide, the bending loss in the optical waveguide can be also reduced.

However, there is no wet etching technique appropriate to a nitride semiconductor laser which emits light within a wavelength range of about 400 nm to 550 nm to be used for a projector or the like. Accordingly, the mesa structure is generally formed using a dry etching process.

In the deep mesa structure where the difference in refractive index Δn of the optical waveguide is large, the side surfaces of the mesa portion (ridge portion) are damaged in the dry etching process, and thus these damaged regions act as non-radiative recombination centers. As a result, the characteristics such as the threshold are degraded rather than improved. Due to such a problem, the shallow-mesa optical waveguide is generally used for the semiconductor laser.

The problem of the damage in the dry etching process to form the deep mesa structure is also true of a nitride semiconductor SLD which emits light within a wavelength range of about 400 nm to 550 nm. However, when the shallow-mesa optical waveguide is used for the SLD, the spontaneously-emitted-light coupling factor A is decreased. As a result, the characteristics are much more degraded than those of the semiconductor laser, and the rising current is increased. Accordingly, in the SLD, the optical waveguide can not be formed as the shallow-mesa optical waveguide without thinking. As described above, the conventional SLD has a problem that the improvement of the efficiency is difficult.

The present disclosure has been conceived in view of the above aspects, and one non-limiting and explanatory embodiment provides a highly-efficient superluminescent diode.

### Solution to Problem

In order to solve the above problem, an aspect of a superluminescent diode is a superluminescent diode having, above a substrate, a layered portion including at least a first cladding layer, a luminescent layer, and a second cladding layer in this order, the superluminescent diode including an optical waveguide provided in the layered portion, the optical waveguide having a refractive-index guiding structure, in which the optical waveguide includes: a first mesa portion formed by processing the second cladding layer into the first mesa portion having a first width; and a second mesa portion formed by processing the first cladding layer, the luminescent layer, and the second cladding layer into the second mesa portion having a second width greater than the first width.

With this, a spontaneously-emitted-light coupling factor can be effectively increased while suppressing the effect of non-radiative recombination. Thus, a highly-efficient superluminescent diode can be achieved.

Furthermore, according to an aspect of the superluminescent diode, a desired distance between a side surface of the first mesa portion and a side surface of the second mesa portion ranges from 0.1 μm to 2.0 μm.

With this, the optical absorption loss in the luminescent layer can be reduced while suppressing the effect of non-radiative recombination. Thus, the effective spontaneously-emitted-light coupling factor can be increased within an appropriate range.

Furthermore, according to an aspect of the superluminescent diode, a distance between a side surface of the first mesa portion and a side surface of the second mesa portion may be constant throughout the optical waveguide.

With this, the effective spontaneously-emitted-light coupling factor can be increased to the maximum level throughout the optical waveguide.

Furthermore, according to an aspect of the superluminescent diode, the first width and the second width may vary gradually in a direction of light propagation through the optical waveguide.

With this, the optical amplification effect in the optical waveguide can be increased, and thus a more highly-efficient superluminescent diode can be achieved.

Furthermore, according to an aspect of the superluminescent diode, the optical waveguide is linear, and the optical waveguide may have a front end face and a rear end face whose normals are tilted relative to a longitudinally extending axis of the optical waveguide.

With this, the superluminescent diode having a light output end face that is a tilted end face can be easily achieved.

Furthermore, according to an aspect of the superluminescent diode, the optical waveguide is linear, the optical waveguide may have a front end face whose normal is tilted relative to a longitudinally extending axis of the optical waveguide, and the optical waveguide may have a rear end face whose normal is parallel to the longitudinally extending axis of the optical waveguide.

With this, a uni-face output superluminescent diode having a reflective end face and a tilted light output end face can be easily achieved through the use of only the linear optical waveguide with a low waveguide loss.

Furthermore, according to an aspect of the superluminescent diode, the optical waveguide includes a linear waveguide portion and a curved waveguide portion, the curved waveguide portion may have an end face that is a front end face of the optical waveguide, and the linear waveguide portion may have an end face that is a rear end face of the optical waveguide.

With this, the uni-face output superluminescent diode having the reflective end face and the tilted light output end face can be easily achieved.

Furthermore, according to an aspect of the superluminescent diode, it is preferable that the curved waveguide portion have a radius of curvature of 1000 μm or more.

With this, the bending loss in the curved optical waveguide can be reduced.

Furthermore, according to an aspect of the superluminescent diode, it is preferable that a high reflectivity layer including a dielectric multilayer film be formed on the rear end face.

With this, the reflectivity of the rear end face is maximized, and thus a more highly-efficient superluminescent diode can be achieved.

Furthermore, according to an aspect of the superluminescent diode, it is preferable that a low reflectivity layer including a dielectric single-layer film or a dielectric multilayer film be formed on the front end face.

With this, the reflectivity of the front end face is minimized, and thus a more highly-efficient superluminescent diode can be achieved.

Alternatively, according to an aspect of the superluminescent diode, it is preferable that a low reflectivity layer including a dielectric single-layer film or a dielectric multilayer film be formed on each of the front end face and the rear end face.

With this, the reflectivity of the front end face is minimized, and thus a more highly-efficient superluminescent diode can be achieved.

Furthermore, according to an aspect of the superluminescent diode, the second mesa portion may have a protrusion spaced apart from the first mesa portion.

With this, a leakage current caused by the etching damage of the side surface of the second mesa portion can be suppressed, and thus a more highly-efficient superluminescent diode can be achieved.

Furthermore, according to an aspect of the superluminescent diode, a first portion of the luminescent layer located under the first mesa portion may have a bandgap smaller than a bandgap of a second portion of the luminescent layer in the second mesa portion located between a side surface of the first mesa portion and a side surface of the second mesa portion.

With this, the light emitted in the portion of the luminescent layer that is located under the first mesa portion is not absorbed in the other portion of the luminescent layer that is located between the side surface of the first mesa portion and the side surface of the second mesa portion. Thus, the effective spontaneously-emitted-light coupling factor can be increased to a level equivalent to that of the deep mesa structure. Accordingly, a more highly-efficient superluminescent diode can be achieved.

Alternatively, according to an aspect of the superluminescent diode, it is preferable that a first portion of the luminescent layer located under the first mesa portion and a second portion of the luminescent layer in the second mesa portion be located at different levels in a stacking direction of the layered portion.

With this, the light emitted in the portion of the luminescent layer that is located under the first mesa portion can be prevented from being absorbed in the other portion of the luminescent layer that is located between the side surface of the first mesa portion and the side surface of the second mesa portion. Thus, the effective spontaneously-emitted-light coupling factor can be increased. Accordingly, a more highly-efficient superluminescent diode can be achieved.

Furthermore, according to an aspect of the superluminescent diode, the layered portion may comprise a III-nitride semiconductor represented as AlₓGa_{y}In_{1-x-y}N, where 0≦x≦1, 0≦y≦1, and 0≦x+y≦1.

With this, it is possible to use the superluminescent diode as a blue light source or a green light source. A blue superluminescent diode can be used as a white light source by combining with a yellow phosphor, or green and red phosphors.

Furthermore, according to an aspect of the superluminescent diode, the layered portion may comprise a III-V compound semiconductor represented as AlₓGa_{y}In_{1-x-y}As_{z}P_{1-z}, where 0≦x≦1, 0≦y≦1, 0≦z≦1, and 0≦x+y≦1.

With this, it is possible to use the superluminescent diode as a red light source. Moreover, a highly-color-reproducible backlight source or a highly-color-reproducible light source for a display device can be achieved by making a white light source using blue, green, and red superluminescent diodes.

Furthermore, according to an aspect of the superluminescent diode, the second cladding layer comprises a conductive transparent material having a refractive index of 2.5 or less, and the conductive transparent material may also act as an electrode. A desired conductive transparent material is indium tin oxide (ITO).

Furthermore, according to an aspect of the superluminescent diode, it is preferable that the first mesa portion have a height of 150 nm or less.

Furthermore, according to an aspect of the superluminescent diode, it is preferable that the first cladding layer comprise AlₓIn₁₋ₓN, where 0<x<1, and the first cladding layer have a refractive index of 2.4 or less.

With this, the vertical optical confinement factor of the optical waveguide Γv can be increased across a wavelength range from blue to green. Thus, a more highly-efficient blue or green superluminescent diode can be achieved.

### Advantageous Effects

A highly-efficient superluminescent diode can be achieved.

### BRIEF DESCRIPTION OF DRAWINGS

These and other objects, advantages and features of the invention will become apparent from the following description thereof taken in conjunction with the accompanying drawings that illustrate a specific embodiment of the present invention.

FIG. 1A illustrates a top view of a superluminescent diode according to an embodiment 1.

FIG. 1B illustrates a cross-sectional view of the superluminescent diode according to the embodiment 1 along the line A-A′ shown in FIG. 1A.

FIG. 1C illustrates a cross-sectional view of the superluminescent diode according to the embodiment 1 along the line B-B′ shown in FIG. 1A.

FIG. 2A illustrates a cross-sectional view (a) and a top view (b) for describing a crystal growth process of a semiconductor layered portion in a method of manufacturing the superluminescent diode according to the embodiment 1.

FIG. 2B illustrates a cross-sectional view (a) and a top view (b) for describing a first mesa portion forming process in the method of manufacturing the superluminescent diode according to the embodiment 1.

FIG. 2C illustrates a cross-sectional view (a) and a top view (b) for describing a second mesa portion forming process in the method of manufacturing the superluminescent diode according to the embodiment 1.

FIG. 2D illustrates a cross-sectional view (a) and a top view (b) for describing an end recess forming process in the method of manufacturing the superluminescent diode according to the embodiment 1.

FIG. 2E illustrates a cross-sectional view (a) and a top view (b) for describing a dielectric insulating layer forming process in the method of manufacturing the superluminescent diode according to the embodiment 1.

FIG. 2F illustrates a cross-sectional view (a) and a top view (b) for describing a p-side electrode forming process in the method of manufacturing the superluminescent diode according to the embodiment 1.

FIG. 2G illustrates a cross-sectional view of a device (a), a top view of the device (b), and a top view of a wafer (c) for describing a pad electrode forming process in the method of manufacturing the superluminescent diode according to the embodiment 1.

FIG. 2H illustrates a cross-sectional view (a) and a top view (b) for describing an n-side electrode forming process in the method of manufacturing the superluminescent diode according to the embodiment 1.

FIG. 2I illustrates a top view of the wafer for describing a wafer dicing process in the method of manufacturing the superluminescent diode according to the embodiment 1.

FIG. 3A illustrates a top view of schematically showing an operation of the superluminescent diode according to the embodiment 1.

FIG. 3B illustrates a cross-sectional view of schematically showing the operation of the superluminescent diode according to the embodiment 1.

FIG. 4 illustrates a graph showing a relationship between a difference in refractive index Δn of an optical waveguide and a spontaneously-emitted-light coupling ratio or a critical angle of the waveguide for a SLD device having a shallow-mesa optical waveguide (comparison example 1) and a SLD device having a deep-mesa optical waveguide (comparison example 2).

FIG. 5A illustrates a top view of a superluminescent diode according to the comparison example 2 having the deep-mesa optical waveguide with a deep-mesa height of Hb.

FIG. 5B illustrates a cross-sectional view of the superluminescent diode according to the comparison example 2 shown in FIG. 5A.

FIG. 6 illustrates a graph schematically showing electrical current vs. optical output characteristics for three semiconductor light-emitting devices: the superluminescent diode according to the embodiment 1, the superluminescent diode according to the comparison example 1, and a semiconductor laser.

FIG. 7A illustrates a graph showing a relationship between an inter-mesa distance d and an rising current (Iop) at an optical output of 5 mW or slope efficiency (Se) for the superluminescent diode according to the embodiment 1.

FIG. 7B illustrates a graph showing a relationship between the inter-mesa distance d and an operating current (Iop) at the optical output of 50 mW for the superluminescent diode according to the embodiment 1.

FIG. 8 illustrates a graph schematically showing an effect of the inter-mesa distance in the superluminescent diode according to the embodiment 1.

FIG. 9A illustrates a top view of a semiconductor laser having an optical waveguide with a two-level mesa structure.

FIG. 9B illustrates a cross-sectional view of the semiconductor laser having the optical waveguide with the two-level mesa structure.

FIG. 10 illustrates a comparison graph showing the threshold current Ith, the slope efficiency Se (at the optical output of 50 mW), and the operating current lop (at the optical output of 50 mW) for three nitride semiconductor lasers: a laser having a shallow-mesa optical waveguide, a laser having a two-level mesa optical waveguide, and a laser having a deep-mesa optical waveguide.

FIG. 11A illustrates a top view of a superluminescent diode according to a variation 1 of the embodiment 1.

FIG. 11B illustrates a cross-sectional view of the superluminescent diode according to the variation 1 of the embodiment 1 along the line A-A′ shown in FIG. 11A.

FIG. 12A illustrates a top view of a superluminescent diode according to a variation 2 of the embodiment 1.

FIG. 12B illustrates a cross-sectional view of the superluminescent diode according to the variation 2 of the embodiment 1 along the line A-A′ shown in FIG. 12A.

FIG. 13A illustrates a top view of a superluminescent diode according to an embodiment 2.

FIG. 13B illustrates a cross-sectional view of the superluminescent diode according to the embodiment 2 along the line A-A′ shown in FIG. 13A.

FIG. 14A illustrates a top view of a superluminescent diode according to an embodiment 3.

FIG. 14B illustrates a cross-sectional view of the superluminescent diode according to the embodiment 3 along the line A-A′ shown in FIG. 14A.

FIG. 15 illustrates a graph showing a relationship between a radius of curvature of an arc portion in a curved waveguide portion and slope efficiency for the superluminescent diode according to the embodiment 3.

FIG. 16A illustrates a top view of a superluminescent diode according to an embodiment 4.

FIG. 16B illustrates a cross-sectional view of the superluminescent diode according to the embodiment 4 along the line A-A′ shown in FIG. 16A.

FIG. 17A illustrates a top view of a superluminescent diode according to an embodiment 5.

FIG. 17B illustrates a cross-sectional view of the superluminescent diode according to the embodiment 5 along the line A-A′ shown in FIG. 17A.

FIG. 18A illustrates a top view of a superluminescent diode according to an embodiment 6.

FIG. 18B illustrates a cross-sectional view of the superluminescent diode according to the embodiment 6 along the line A-A′ shown in FIG. 18A.

FIG. 19A illustrates a top view of a superluminescent diode according to an embodiment 7.

FIG. 19B illustrates a cross-sectional view of the superluminescent diode according to the embodiment 7 along the line A-A′ shown in FIG. 19A.

FIG. 20 illustrates a graph showing electrical current vs. optical output characteristics for a semiconductor laser and a superluminescent diode.

FIG. 21A illustrates a cross-sectional view of a semiconductor light-emitting device having a shallow-mesa optical waveguide.

FIG. 21B illustrates a cross-sectional view of a semiconductor light-emitting device having a deep-mesa optical waveguide.

### DESCRIPTION OF EMBODIMENTS

The following describes exemplary embodiments of the superluminescent diode with reference to the drawings. It should be noted that any one of the following embodiments is a preferred example of the present disclosure, and therefore the present disclosure is not limited to these embodiments. The numerical values, shapes, materials, constituent elements, the arrangement and connection of the constituent elements, steps, the processing order of the steps etc. shown in the following embodiments are mere examples, and thus do not limit the present disclosure. Thus, among the constituent elements in the following embodiments, constituent elements not recited in any of the independent claims indicating the most generic concept of the present disclosure are not always required to achieve the aim of the present disclosure, but are described as preferable constituent elements.

In the drawings, “c”, “a”, and “m” denote plane directions of hexagonal GaN-based crystal, where “c” denotes a normal vector to a (0001) plane, i.e. c-axis, “a” denotes a normal vector to a (11-20) plane and its equivalent planes, i.e. a-axis, and “m” denotes a normal vector to a (1-100) plane and its equivalent planes, i.e. m-axis. In the specification, for the sake of convenience, a negative sign “−” in Miller indices of the plane directions represents inversion of an index following the negative sign. In the following embodiments, the most usual plane direction of a nitride semiconductor is shown in the drawings, but the plane direction is not limited to this. Any plane direction is possible.

It should be noted that the drawings are schematic views, and not necessarily illustrated in detail. Furthermore, in the following drawings, the identical constitution elements are numbered the same, and details thereof are omitted or briefly described.

### Embodiment 1

First, the following describes a superluminescent diode (SLD) 100 according to an embodiment 1 with reference to the drawings. It should be noted that the SLD 100 according to the embodiment is described as a nitride semiconductor SLD device which is a blue SLD device for emitting blue light in a wavelength range of about 400 nm to 450 nm.

The SLD 100 according to the embodiment 1 has, above a substrate, a layered portion including at least a first cladding layer, a luminescent layer, and a second cladding layer in this order, and the layered portion is provided with an optical waveguide that includes a first mesa portion having a shallow mesa depth and a second mesa portion having a deep mesa depth and has a refractive-index guiding structure. Furthermore, the optical waveguide according to the embodiment has a front end face (light output end face) tilted relative thereto and a rear end face perpendicular thereto.

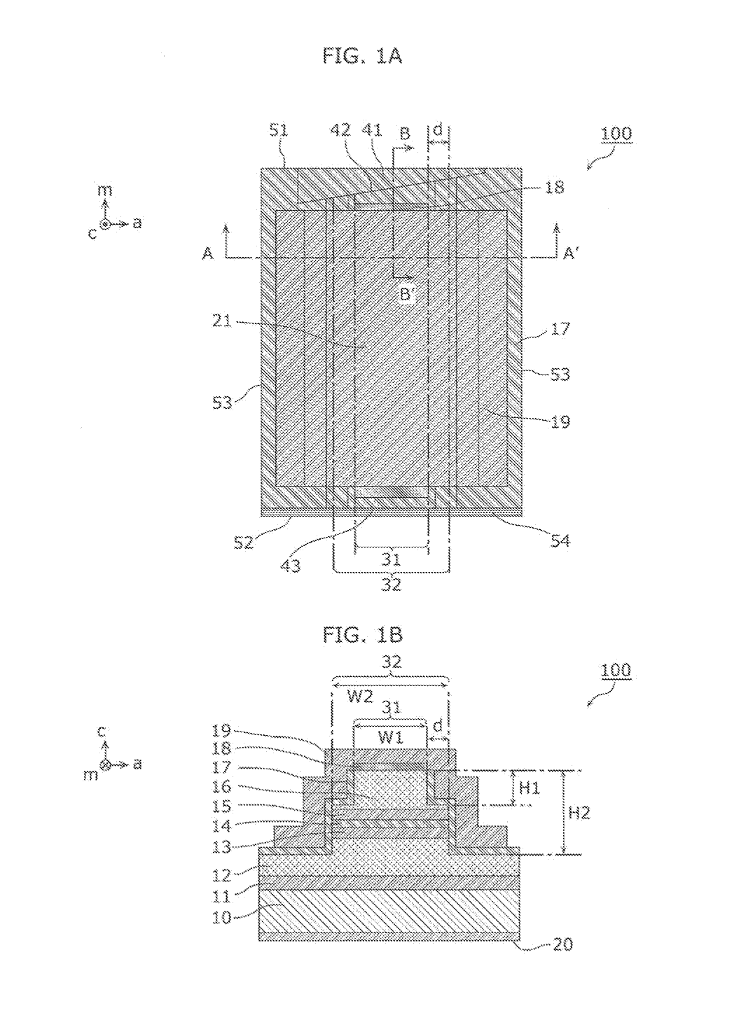

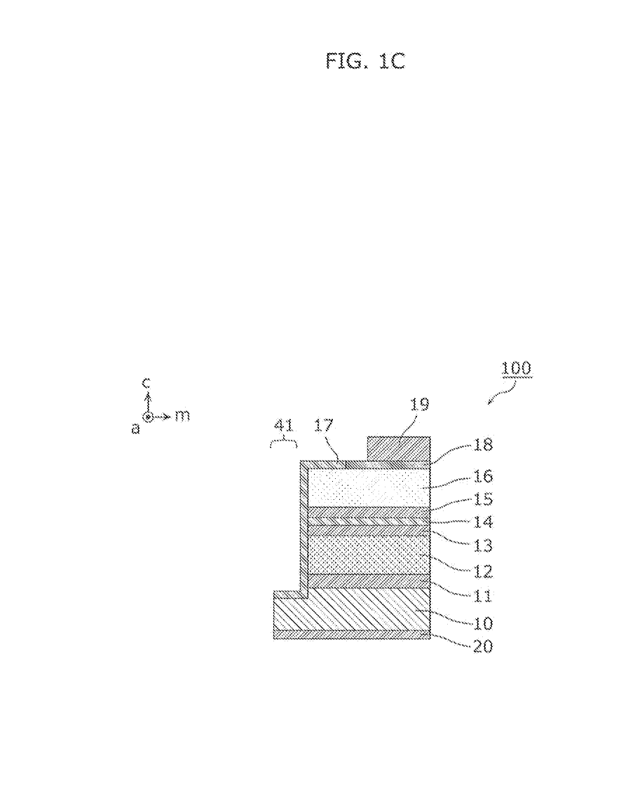

The following describes the specific structure of the SLD 100 according to the embodiment in detail with reference to FIG. 1A to FIG. 1C. FIG. 1A illustrates a top view of the SLD according to the embodiment 1. FIG. 1B illustrates a cross-sectional view of the SLD according to the embodiment 1 along the line A-A′ in FIG. 1A, and FIG. 1C illustrates a cross-sectional view of the SLD according to the embodiment 1 along the line B-B′ in FIG. 1A.

As shown in FIG. 1A to FIG. 1C, the SLD 100 according to the embodiment includes a substrate 10 comprising n-type GaN, and a semiconductor layered portion in which a buffer layer 11 comprising n-type (the first conductive type) GaN, a lower cladding layer 12 comprising n-type AlGaN (the first cladding layer), a lower guiding layer 13 comprising n-type GaN (the first guiding layer), a luminescent layer 14 having a multiquantum well structure (an active layer), an upper guiding layer 15 comprising undoped or p-type (the second conductive type) GaN, and a p-type upper cladding layer 16 that is a strained superlattice layer comprising AlGaN and GaN (the second cladding layer) are sequentially formed above the substrate 10. It should be noted that a carrier over-flow suppression (OFS) layer comprising AlGaN (not shown) is formed between the upper guiding layer 15 and the upper cladding layer 16, and a contact layer comprising p-type GaN (not shown) is formed on the upper cladding layer 16.

In the upper cladding layer 16, a ridge-shaped first mesa portion 31 having a predetermined ridge width W1 (a stripe width), i.e. the first width, and a predetermined height H1, i.e. the first height, is formed. The first mesa portion 31 is formed by processing the upper cladding layer 16 into a vertical mesa structure having the predetermined ridge width W1. The first mesa portion 31 according to the embodiment is protruded upward in a direction perpendicular to the main surface of the substrate 10 and has a stripe shape in the top view as shown in FIG. 1A. It should be noted that a portion of the upper cladding layer 16 where the first mesa portion 31 is not formed (in other words, the dug portion) is referred to as a thin flat portion.

Furthermore, in the embodiment, the ridge-shaped second mesa portion 32 having a mesa depth reaching the lower cladding layer 12 is formed outside the first mesa portion 31. In other words, the second mesa portion 32 has a predetermined ridge width W2 (a stripe width) greater than the ridge width W1 of the first mesa portion 31, and a height H2 greater than the height H1 of the first mesa portion 31. The second mesa portion 32 is formed by processing the semiconductor layered portion formed outside the first mesa portion 31, from the top layer down to the lower cladding layer 12, into a vertical mesa structure having the predetermined ridge width W2. Like the first mesa portion 31, the second mesa portion 32 according to the embodiment is protruded upward in a direction perpendicular to the main surface of the substrate 10 and has a stripe shape in the top view as shown in FIG. 1A. It should be noted that a portion of the lower cladding layer 12 where the second mesa portion 32 is not formed (in other words, the dug portion) is referred to as a thin flat portion.

Thus, the optical waveguide 21 according to the embodiment has a two-level mesa structure which includes the first mesa portion 31 having a ridge side surface formed from the upper cladding layer 16 and the second mesa portion 32 having a width greater than that of the first mesa portion 31 and a ridge side surface formed from at least the luminescent layer 14. With this, the spontaneously-emitted-light coupling factor A in the above-mentioned Equation 1 can be increased. As a result, the optical output increases and thus the rising current decreases. Accordingly, the efficiency can be improved.

Furthermore, the two-level mesa optical waveguide 21 is covered with the SiO₂ dielectric insulating layer 17 having an opening on the top surface of the first mesa portion 31 (the upside of the protrusion of the upper cladding layer 16). The dielectric insulating layer 17 is formed on the side surfaces of the upper cladding layer 16 included in the respective ridge side surfaces of the first mesa portion 31, the upper surfaces of the thin flat portions of the upper cladding layer 16, the respective side surfaces of the upper cladding layer 16, the upper guiding layer 15, the luminescent layer 14, the lower guiding layer 13, and the lower cladding layer 12 included in the respective ridge side surfaces of the second mesa portion 32, and the upper surfaces of the thin flat portions of the lower cladding layer 12.

The p-side electrode is formed on the top surface of the first mesa portion 31 (the upside of the protrusion of the upper cladding layer 16) so as to fill the opening of the dielectric insulating layer 17. Furthermore, the pad electrode 19 electrically connected to the p-side electrode 18 is formed on the p-side electrode 18 and the dielectric insulating layer 17. It should be noted that the n-side electrode 20 is formed on the back surface of the substrate 10, i.e. a surface opposite to the surface of the substrate 10 on which the lower cladding layer 12 is formed.

Furthermore, as shown in FIG. 1A and FIG. 1C, the end recess 41 is formed in a forward face 51 of the SLD device using an etching process, and an inner side surface of the end recess 41 is used as the front end face 42 of the optical waveguide 21. The front end face 42 is the light output end face from which light emitted in the luminescent layer 14 and propagating through the optical waveguide 21 exits to the outside of the device, and is formed so as to make a predetermined angle with respect to the forward face 51. In other words, the normal of the front end face 42 of the optical waveguide 21 is tilted relative to a longitudinally extending axis (a stripe axis) of the optical waveguide 21. It should be noted that the front end face 42 is a low reflective surface so that light propagating through the optical waveguide 21 can exit to the outside of the device. For example, the low reflective surface can be made by forming, on the front end face 42, a low reflectivity layer including a dielectric single-layer film or a dielectric multilayer film. Thus, the front end face 42 formed as the low reflective surface allows the reflectivity to be minimized.

On the other hand, a rear face 52 is made by forming a dielectric multilayer film 54 on the rear end face 43 of the optical waveguide 21. The dielectric multilayer film 54 is a high reflectivity layer in which dielectric films such as SiO₂/ZrO₂ are stacked. Thus, the reflectivity of the rear end face 43 can be maximized by forming the high reflectivity layer on the rear end face 43. Furthermore, the rear end face 43 of the optical waveguide is parallel to the rear face 52. In other words, the normal to the rear end face 43 of the optical waveguide 21 is parallel to the longitudinally extending axis of the linear optical waveguide 21. It should be noted that the side surface 53 of the SLD device is a surface of separation.

As shown in FIG. 1C, the end recess 41 in the forward face 51 is an etched recess formed by etching down to the substrate 10. The surface of the end recess 41 exposed by the etching process is covered with the dielectric insulating layer 17.

### (Manufacturing Method)

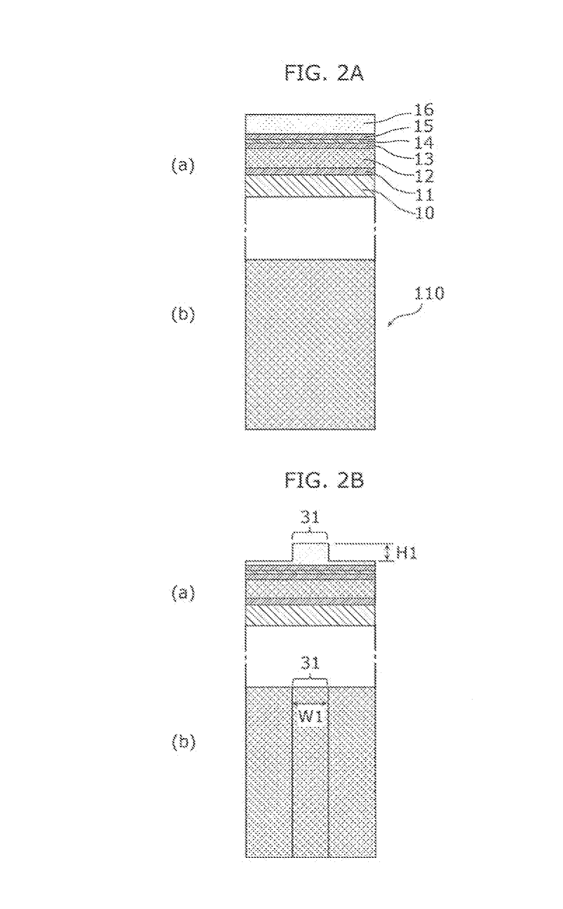

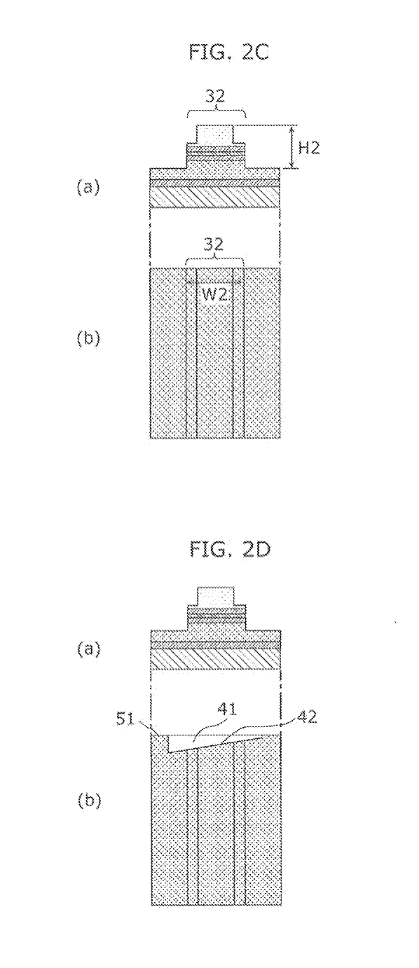

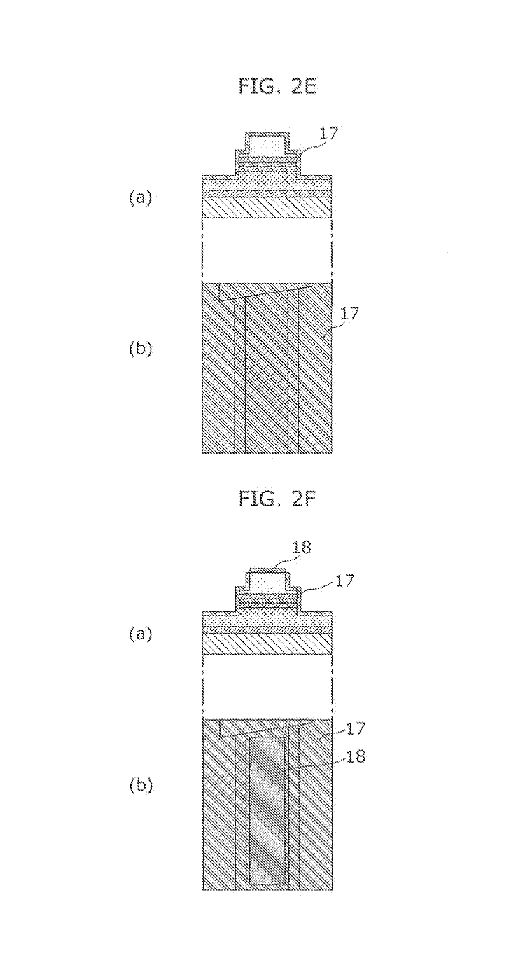

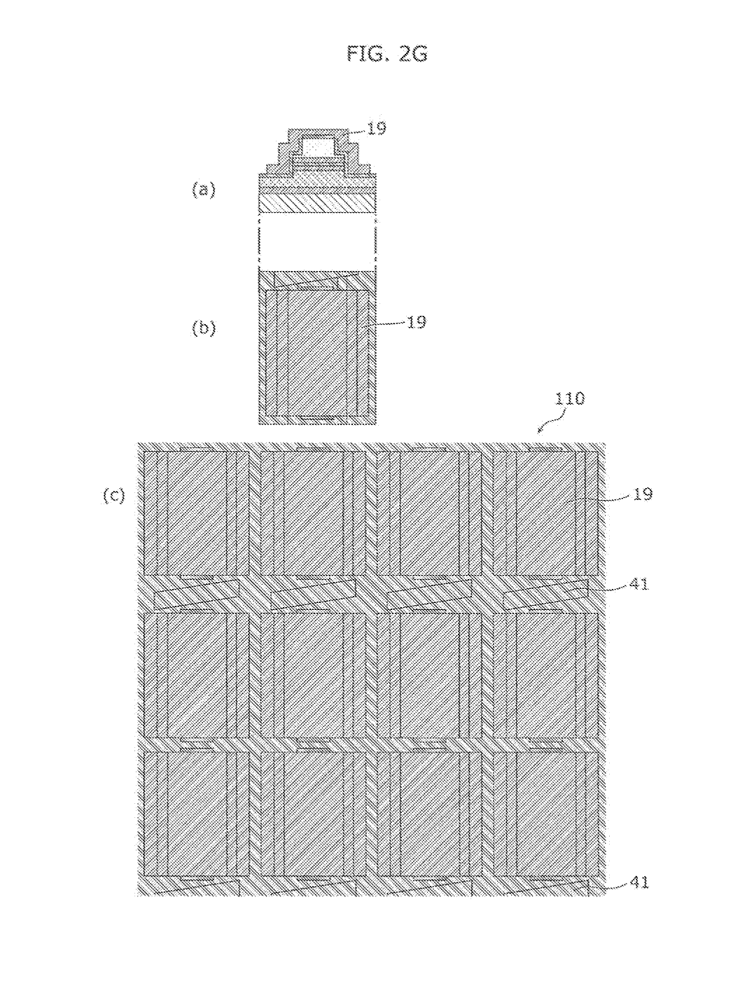

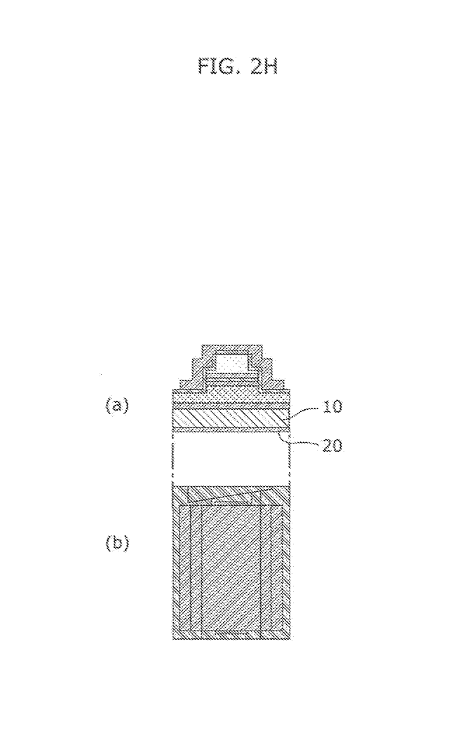

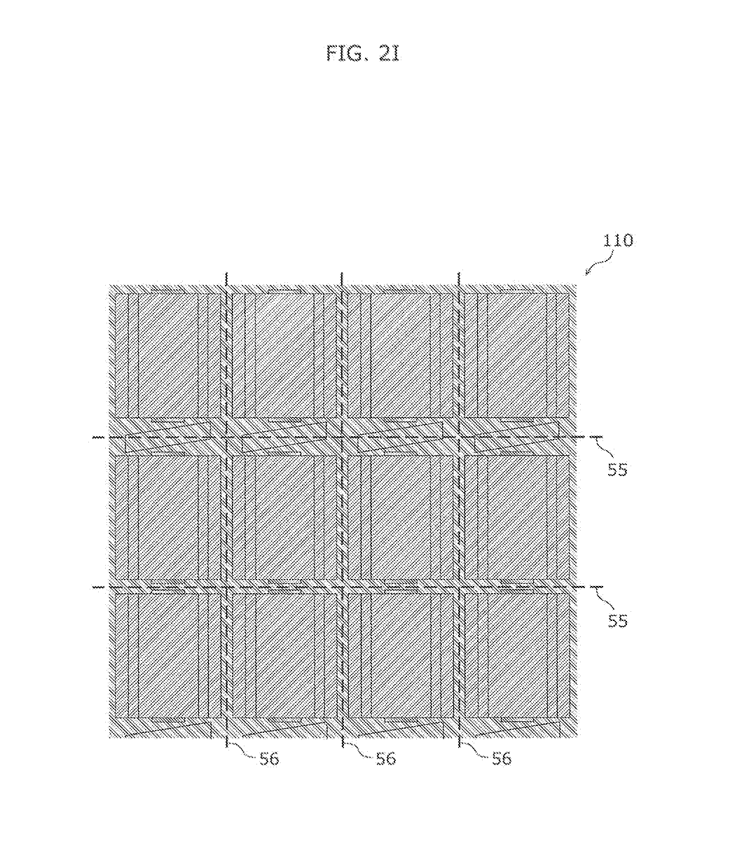

Next, a method of manufacturing the SLDs 100 according to the embodiment 1 is described with reference to FIG. 2A to FIG. 2I. FIG. 2A to FIG. 2I each includes a cross-sectional view and a top view for describing a corresponding one of the process steps in the method of manufacturing the SLDs 100 according to the embodiment 1.

### (Semiconductor Layered Portion Crystal Growth Process)

First, as shown in (a) of FIG. 2A, for example, using a metal organic chemical vapor deposition (MOCVD) method, a buffer layer 11 comprising n-type GaN and having a thickness of 1 μm and a lower cladding layer 12 comprising n-type Al_{0.05}Ga_{0.95}N and having a thickness of 2 μm are sequentially grown on the main surface, i.e. a (0001) plane, of the substrate 10 comprising n-type hexagonal GaN and having a carrier density of about 1×10¹⁸ cm⁻³.

Subsequently, on the lower cladding layer 12, the lower guiding layer 13 comprising n-type GaN and having a thickness of 0.10 μm, and the luminescent layer 14 having a three-period multiquantum well (MQW) structure of a barrier layer comprising In_{0.02}Ga_{0.98}N and a quantum well layer comprising In_{0.16}Ga_{0.84}N are grown sequentially.

Subsequently, on the luminescent layer 14, the upper guiding layer 15 comprising undoped or p-type GaN and having a thickness of 0.05 μm is grown. After this, on the upper guiding layer 15, a carrier over-flow suppression (OFS) layer comprising Al_{0.02}Ga_{0.80}N and having a thickness of 10 nm is grown (not shown).

Subsequently, an upper cladding layer 16 is grown on the OFS layer. This upper cladding layer has a 120-period structure of a p-type Al_{0.10}Ga_{0.90}N layer and a GaN layer each having a thickness of 2 nm, and is also a strained superlattice layer having a thickness of 0.50 μm. It should be noted that a contact layer comprising p-type GaN and having a thickness of 0.05 μm is grown on the upper cladding layer 16 (not shown).

With this, as shown in (b) of FIG. 2A, a wafer 110 in which the semiconductor layered portion is formed above the substrate 10 can be achieved.

It should be noted that, in the semiconductor layered portion, each of the n-type semiconductor layers is doped with silicon (Si) or the like, which acts as a donor impurity, to a concentration of about 5×10¹⁷ cm⁻³ to 10×10¹⁷ cm⁻³. On the other hand, each of the p-type semiconductor layers is doped with magnesium (Mg) or the like, which acts as an acceptor impurity, to a concentration of about 1×10¹⁹ cm⁻³. The p-type contact layer that is a top layer is doped with Mg to a high concentration of about 1×10²⁰ cm⁻³. Furthermore, in the OFS layer, the band gap is increased by changing the composition of Al to a high level of 20%. Accordingly, due to the OFS layer having a large band gap, the mobility of electrons present in the conduction band is higher than that of holes present in the valence band. This prevents carriers from passing through the luminescent layer 14 to non-radiatively recombine in the semiconductor layers other than the luminescent layer 14.

It should be noted that the semiconductor layered portion structure according to the embodiment is an example and thus the semiconductor layered portion structure and the growth method are not limited to the foregoing embodiment. For example, instead of the MOCVD, a method capable of growing the GaN-based semiconductor layered portion, such as a molecular beam epitaxy (MBE) method or a chemical beam epitaxy (CBE) method, may be used as the crystal growth method for forming the semiconductor layered portion.

For materials to be used in the MOCVD method, for example, trimethylgallium (TMG), trimethylindium (TMI), trimethylaluminium (TMA), and ammonia (NH₃) can be used as a source of Ga, a source of In, a source of Al, and a source of N, respectively. Furthermore, silane (SiH₄) gas can be used as a source of Si that acts as an n-type impurity, and biscyclopentadienyl magnesium (Cp₂Mg) can be used as a source of Mg that acts as a p-type impurity.

### (Forming Process of Two-Level Mesa Waveguide)

Next, using a CVD method, a first SiO₂ film (not shown) having a thickness of 200 nm is deposited on the entire surface of the p-type contact layer. After this, a heat treatment is performed on the wafer 110 in a nitrogen (N₂) atmosphere at a temperature of 850° C. for 20 minutes, thereby activating Mg in each of the p-type semiconductor layers.

Subsequently, using a dry etching method such as lithography or reactive ion etching (RIE), the first SiO₂ film is patterned by etching the first SiO₂ film, to form a first mask film comprising SiO₂ in a region where the first mesa portion 31 is to be formed.

After this, using the first mask film, in an inductively coupled plasma (ICP) dry etching process using chlorine-based gas such as chlorine (Cl₂) gas, silicon tetrachloride (SiCl₄) gas, or boron trichloride (BCl₃) gas, the p-type contact layer and the upper side of the upper cladding layer 16 under it are etched about 0.4 μm in total, and then the first mask film is removed using a buffered hydrofluoric acid (BHF) solution. With this, as shown in (a) and (b) of FIG. 2B, the first mesa portion 31 having a ridge width W1 and a height H1 can be formed. It should be noted that in the embodiment, the first mesa portion 31 has the ridge width (a width of the bottom) W1 of about 1.5 μm. It should be noted that a desired ridge width W1 ranges from 1 μm to 20 μm.

Subsequently, once again, a second SiO₂ film having a thickness of 200 nm is deposited on the entire surface of the wafer using the CVD method, and then the SiO₂ film is patterned using the RIE method in a similar manner to the foregoing, thereby forming the second mask film comprising SiO₂. After this, the ICP dry etching process using the chlorine-based gas is performed and the second mask film is removed using the BHF. With this, as shown in (a) and (b) of FIG. 2C, the second mesa portion 32 having a ridge width W2 and a height H2 can be formed.

In this case, the etching depth which is the height H2 of the second mesa portion 32 is needed to be a depth reaching at least the lower cladding layer 12. In the embodiment, this depth is 1 μm. Furthermore, a distance between the side surface of the first mesa portion 31 and the side surface of the second mesa portion 32 (hereinafter referred to as an “inter-mesa distance d”) is 1.5 μm. In the embodiment, the inter-mesa distance d can be expressed as one-half of a difference between the ridge width W2 of the second mesa portion 32 and the ridge width W1 of the first mesa portion 31 ((W2−W1)/2). Although the details are described below, a desired mesa distance d ranges from about 0.1 μm to 2.0 μm.

### (Forming Process of End Recess)

Next, once again, a third SiO8 film having a thickness of 800 nm is deposited on the entire surface of the wafer using the CVD method, and then the SiO2 film is patterned using the RIE method in a similar manner to the foregoing, thereby forming the third mask film comprising SiO2. After this, the ICP dry etching process using the chlorine-based gas is performed and the third mask film is removed using the BHF. With this, as shown in (b) of FIG. 2D, the end recess 41 is formed. Thus, the front end face 42 can be formed.

In the embodiment, the depth of the end recess 41 is 3 μm. The front end face 42 that also acts as a side surface of the end recess 41 is more inward than the forward face 51 of the device. In view of this, in order to prevent the optical loss (reflection or scattering of light) caused by the bottom of the end recess 41, a greater depth is preferred for the end recess 41, and a desired depth is at least 2 μm.

Furthermore, the end recess 41 is formed so that the front end face 42 is tilted relative to the optical waveguide 21. Thus, the reflectivity of the front end face 42 (a mode reflectivity of the waveguide) can be considerably decreased by forming the front end face 42 as a tilted end face, thereby suppressing lasing and allowing the SLD operation. It should be noted that the reflectivity decreases for a greater tilting angle of the front end face 42, but the tilting angle is required not to be more than Brewster's angle. In view of this, a desired tilting angle of the front end face 42 ranges from about 5 to 20 degrees. In the embodiment, the tilting angle is 10 degrees.

(Forming Process of Dielectric Insulating Layer and p-Type Electrode)

Next, as shown in (a) and (b) of FIG. 2E, once again, using the CVD method, the dielectric insulating layer 17 which is a fourth SiO₂ film having a thickness of 300 nm is deposited on the entire surface of the wafer. Subsequently, in the lithography process and the wet etching process using the buffered hydrofluoric acid solution, the top surface of the first mesa portion 31, i.e. the opening in which the p-type contact layer is exposed, is formed in the dielectric insulating layer 17. It should be noted that the opening of the dielectric insulating layer 17 may be formed by etching back a resist film instead of the lithography.

Subsequently, as shown in (a) and (b) of FIG. 2F, using an electron beam evaporation method, the p-side electrode 18 comprising palladium (Pa)/platinum (Pt) is formed so as to fill the opening of the dielectric insulating layer 17, in other words, have a planar shape equivalent to that of the opening of the dielectric insulating layer 17. In the embodiment, the p-side electrode 18 is formed to have a Pd film and a Pt film each having a thickness of 50 nm. After this, a heat treatment is performed at a temperature of 400° C., and thus a good contact resistance of 2×10⁻⁴ Ωcm² or less can be achieved.

### (Forming Process of Pad Electrode)

Next, as shown in (a) to (c) of FIG. 2G, using the lithography method and the electron beam evaporation method, the pad electrode 19 comprising titanium (Ti)/platinum (Pt)/gold (Au) is formed on the dielectric insulating layer 17 including the p-side electrode 18 so as to be electrically connected to the p-side electrode 18. In this case, the thickness of Ti, the thickness of Pt, and the thickness of Au are 50 nm, 50 nm, and 500 nm, respectively.

It should be noted that, as shown in (c) of FIG. 2G, the substrate 10 is generally in a form of a wafer 110, and the SLD devices are formed in a matrix on the main surface of the substrate 10. In view of this, when the substrate 10, which is in the form of the wafer 110, is diced into the individual SLD devices through cleavage, if the pad electrodes 19 are formed without space between the devices, the p-side electrode 18 firmly attached to the pad electrode 19 may be removed from the p-type contact layer. Accordingly, it is desirable that adjacent ones of the pad electrodes 19 are separate from each other. Furthermore, when the thickness of a top layer in the pad electrode 19, i.e. the Au layer, is increased to 3 μm or more using an electrolytic plating method, heat from the luminescent layer 14 can be effectively released. In other words, the plated electrode including the Au layer having a thickness of 3 μm or more can improve the reliability of the SLD device. It should be noted that, as shown in (c) of FIG. 2G, a pair of the end recesses 41 is formed for the adjacent SLD devices.

(Forming Process of n-Type Electrode)

Next, the substrate 10 is thinned to a thickness of about 100 μm by grinding and polishing the back surface of the substrate 10. Subsequently, as shown in (a) and (b) of FIG. 2H, the n-side electrode 20 comprising Ti/Pt/Au is formed on the back surface of the thinned substrate 10. In the embodiment, the thickness of Ti, the thickness of Pt, and the thickness of Au are 10 nm, 50 nm, and 100 nm, respectively. With this, a good contact resistance of about 1×10⁻⁴ Ωcm² can be achieved.

In this step, it is desirable that an electrode pattern is formed as a recognition pattern in the following process step of cleaving and packaging, by etching only the Au film, which is a top layer in the n-side electrode 20, using the lithography method and the wet etching method. Alternatively, the electrode pattern may be formed by lithography, deposition, and lift-off.

It should be noted that (i) a mechanical polishing method using diamond slurries or colloidal silicas or (ii) a chemical mechanical polishing method using alkaline solution such as potassium hydroxide solution in combination with diamond slurries or colloidal silicas may be used for a method of polishing the substrate 10.

### (Cleaving and Packaging Process)

Next, as shown in FIG. 2I, a primary separation process is performed in which the wafer 110 is separated into bars each of which is a set of the SLD devices arranged in a row, by cutting the wafer along the first cutting lines 55. With this, the forward face 51 and the rear end face 43 of the SLD device are formed.

In this step, the wafer is cut through cleavage utilizing the cleavage property thereof. In this case, it is possible to use, as cleavage assistant grooves, grooves that are formed along the first cutting lines 55 on the wafer 110 by scribing with a diamond needle or a laser as needed. It should be noted that the scribed grooves may be formed only at the end portions of the first cutting lines 55, or in a dotted pattern between the devices. After this, the wafer is broken along the first cutting lines 55. This primary cleavage process forms a front edge face and a rear edge face.

Subsequently, using the CVD method, a sputtering method, or the like, the dielectric multilayer film 54 comprising SiO₂/TiO₂ for example and having a reflectivity of 90% or more is formed on the rear end faces 43 of the bar which is the set of the SLD devices arranged in a row (not shown). In this step, subsequently, the dielectric single-layer film or dielectric multilayer film having a reflectivity of 1% or less may be formed on the front end faces 42 of the bar using the CVD method or the sputtering method like the above. In this case, the dielectric insulating layer 17 protecting the front end faces 42 may be removed as needed.

Next, as shown in the same drawing, a secondary separation process (secondary cleavage) is performed in which cleavage assistant grooves are formed parallel to a longitudinal direction of an optical resonator along second cutting lines 56 by scribing with a diamond needle or a laser as needed. With this, the devices are separated, and thus the single SLD device can be achieved.

It should be noted that after this, the SLD device is mounted in a desired package such as a CAN package and then wired. Thus, the blue SLD devices can be manufactured.

### (Operation and Effect)

Next, the operation and the effect of the SLD 100 according to the embodiment 1 is described with reference to the drawings.

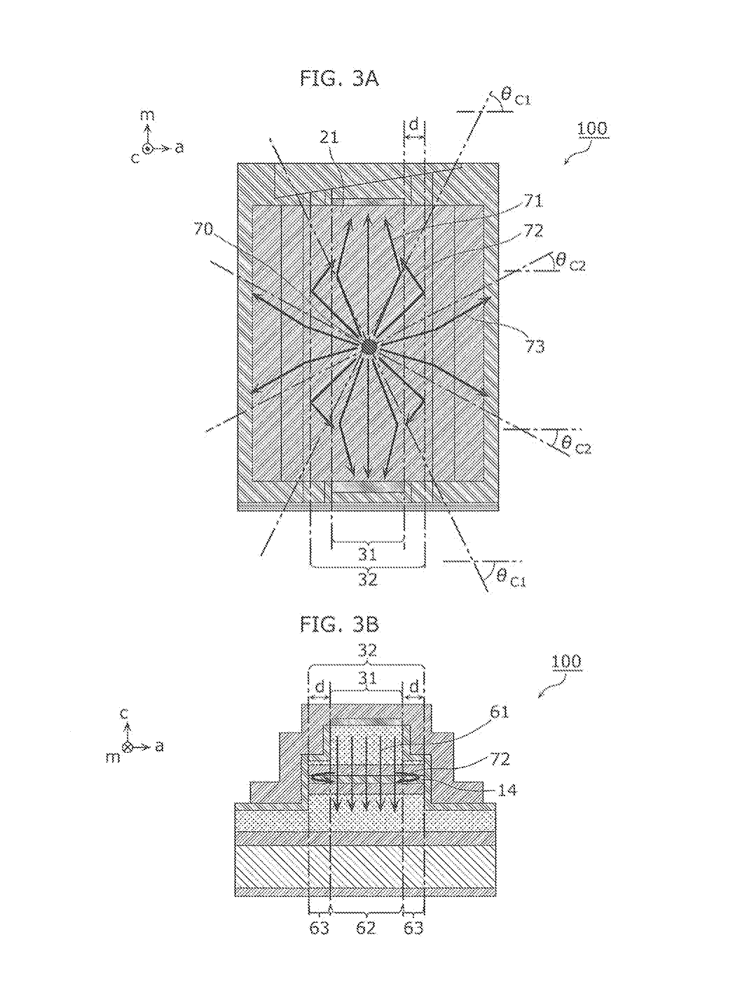

FIG. 3A and FIG. 3B illustrates a top view and a cross-sectional view for describing the internal mechanism of the SLD 100 according to the embodiment shown in FIG. 1A and FIG. 1B, respectively.

As shown in FIG. 3B, in the SLD having the two-level mesa optical waveguide as described in the embodiment, recombination light emission occurs in a portion of the luminescent layer 14 located under the p-side electrode due to current carries 61 injected from the p-side electrode 18. At this time, for example, as shown in FIG. 3A, the light emitted from a light emission point 70 in the luminescent layer 14 randomly radiates in all directions. In this specification, light emission in an in-plane direction of the luminescent layer 14 is taken for the sake of briefness.

In this case, the first mesa portion 31 has a difference in effective refractive index between the inside and the outside, and thus only a part of the light emitted from the light emission point 70, i.e. light having an angle of incidence to the first mesa portion 31 greater than a first critical angle θ_{C1}, is totally reflected off the side surface of the first mesa portion 31. Then, this totally-reflected light wave passes through the optical waveguide 21 as a first light 71 propagating through the first mesa portion 31.

Furthermore, another part of the light emitted from the light emission point 70, i.e. light having an angle of incidence to the first mesa portion 31 smaller than the first critical angle θ_{C1} and an angle of incidence to the second mesa portion 32 greater than a second critical angle θ_{C2}, is totally reflected off the side surface of the second mesa portion 32. Then, this totally-reflected light wave passes through the optical waveguide 21 as a second light 72 propagating through the first mesa portion 31 and the second mesa portion 32.

It should be noted that the remaining light, i.e. light having an angle of incidence to the second mesa portion 32 smaller than the second critical angle θ_{C2}, exits to the outside of the optical waveguide 21 as radiated light 73.

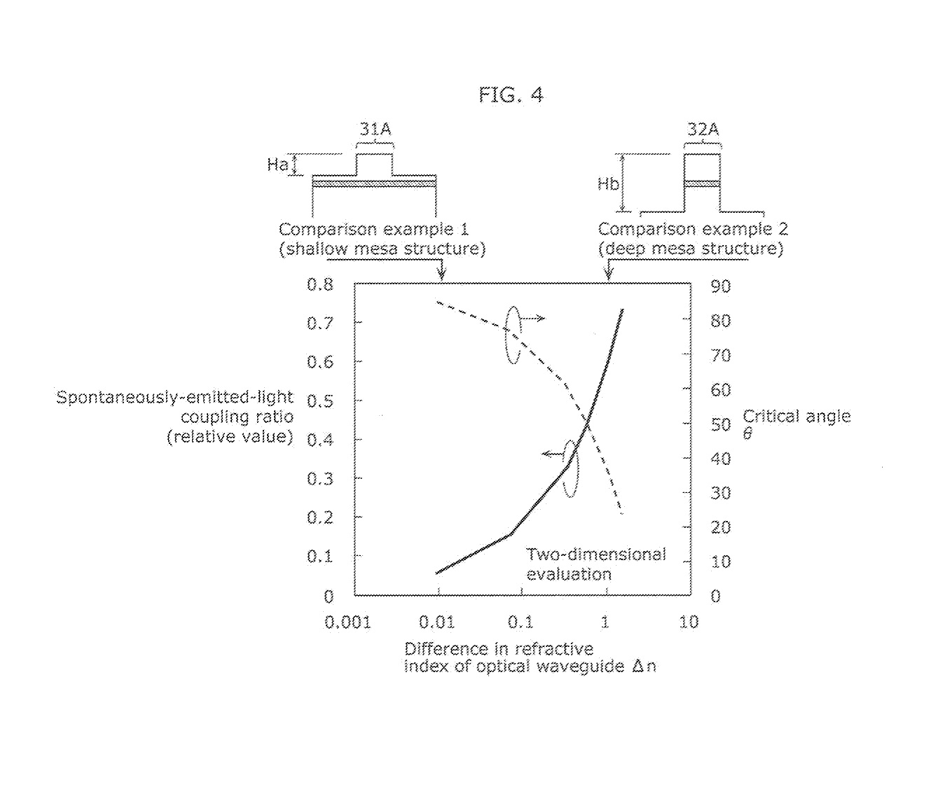

Here, the characteristics for a SLD device having a shallow-mesa optical waveguide in which a shallow mesa portion 31A has a height of Ha (comparison example 1) and a SLD device having a deep-mesa optical waveguide in which a deep mesa portion 32A has a height of Hb (>Ha) (comparison example 2) are described with reference to FIG. 4. FIG. 4 illustrates a graph showing a relationship between a difference in refractive index Δn of the optical waveguide and a spontaneously-emitted-light coupling ratio or a critical angle of the waveguide for the SLD device having the shallow-mesa optical waveguide (comparison example 1) and the SLD device having the deep-mesa optical waveguide (comparison example 2).

FIG. 4 shows that the difference in refractive index Δn inside or outside the optical waveguide increases with increasing the mesa height. In addition, FIG. 4 shows that the critical angle θc of light propagating through the optical waveguide decreases with increasing the difference in refractive index Δn of the optical waveguide.

However, like the comparison example 1, the SLD device having the shallow-mesa optical waveguide which is formed by etching only down to the upper cladding layer has a small effective difference in refractive index Δn of 1×10⁻² or less because the light area and the confinement structure are spatially separated from each other. As a result, the SLD device according to the comparison example 1 of the shallow mesa structure has a critical angle θ_{C} of 85 degrees or more, and the ratio of light propagating through the optical waveguide to light emitted randomly in an in-line direction (spontaneously emitted light) (spontaneously-emitted-light coupling ratio) is less than 10%.

In contrast, like the comparison example 2, the SLD device having the deep-mesa optical waveguide which is formed by etching down to the lower cladding layer has a large difference in refractive index Δn of 1 or more because the difference in refractive index between the semiconductor layer and the dielectric insulating layer covering the deep mesa portion 32A is Δn with no change. As a result, the SLD device according to the comparison example 2 of the deep mesa structure can have a critical angle θ_{C} of 30 degrees or less. Thus, the comparison example 2 can have a spontaneously-emitted-light coupling ratio of 70% or more which is about ten times as great as that of the comparison example 1.

The spontaneously-emitted-light coupling factor A shown in the Equation 1 is proportional to the spontaneously-emitted-light coupling ratio. Accordingly, the rising current of the SLD can be decreased with increasing the spontaneously-emitted-light coupling ratio. In other words, a desirable structure for the SLD is the deep mesa structure, ideally.

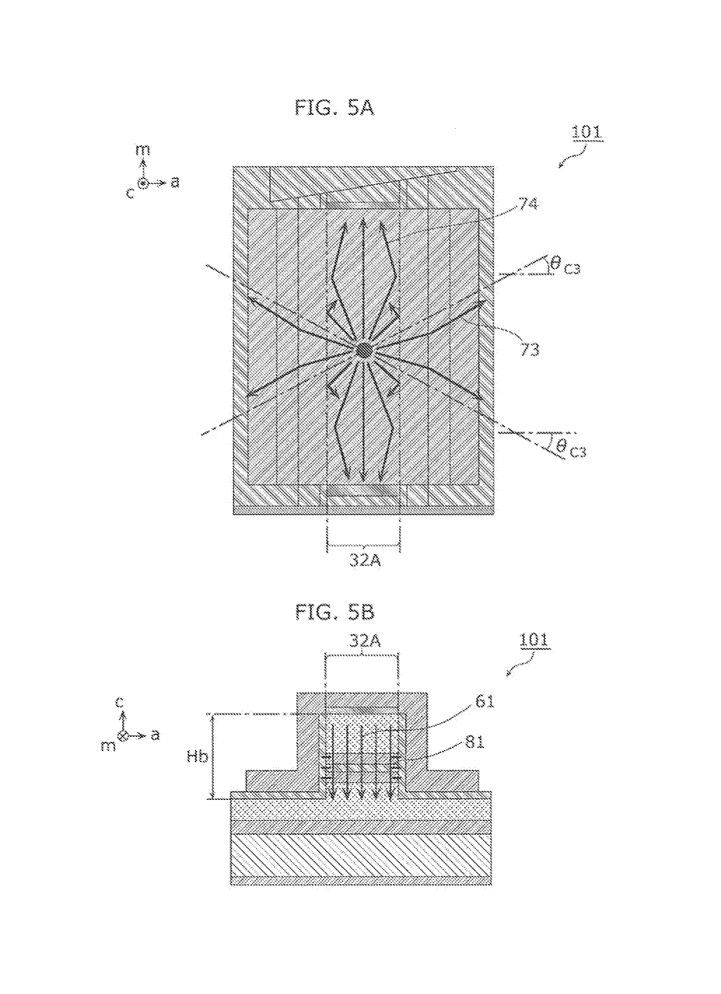

Accordingly, for example, as shown in FIG. 5A and FIG. 5B, when the SLD 101 having the simple deep-mesa optical waveguide like the comparison example 2 is manufactured, the critical angle θ_{C3} is small as shown in FIG. 5A. It should be noted that FIG. 5A illustrates a top view of the SLD according to the comparison example 2 having the deep-mesa optical waveguide in which the deep mesa portion 32A has a height of Hb, and FIG. 5B illustrates a cross-sectional view of the same SLD.

However, after a considerable study of this, the inventors found that, in the nitride semiconductor SLD, when the deep mesa portion 32A was formed using the dry etching method, surface states and the like induced by dry-etching damage or the like appeared at the side surface of the deep mesa portion 32A and the surface states and the like acted as non-radiative recombination centers 81, thereby resulting in degraded characteristics rather than improved characteristics.

In view of this, as shown in FIG. 3A and FIG. 3B, the SLD 100 according to the embodiment has the two-level mesa optical waveguide including the first mesa portion 31 and the second mesa portion 32. Thus, due to the two-level mesa structure of the optical waveguide, in the first mesa portion 31, current can be confined, and in the second mesa portion 32, the second light 72 can be confined to the waveguide.

Thus, due to the two-level mesa structure of the optical waveguide, the spontaneously-emitted-light coupling factor A can be increased while suppressing the effect of non-radiative recombination in the second mesa portion 32. Accordingly, the rising current is reduced and the slope efficiency is improved, and thus the highly-efficient SLD can be achieved.

Next, the following describes a desired range of the inter-mesa distance d.

In the SLD 100 according to the embodiment, a region located under the first mesa portion 31 in the second mesa portion 32 is a current injection region 62 to which current 61 is injected. In this current injection region 62, when the SLD is ON, a population inversion occurs, the luminescent layer 14 becomes transparent, and light is amplified.

On the other hand, a region other than the region located under the first mesa portion 31 in the second mesa portion 32, i.e. a region in the second mesa portion 32 located outside the first mesa portion 31, is a current non-injection region 63 to which the current 61 is not injected. In the current non-injection region 63, light is absorbed in the luminescent layer 14 because carriers do not exist.

This current non-injection region 63 increases with increasing the inter-mesa distance d. Accordingly, when the inter-mesa distance d is too great, the second light 72 is totally absorbed in the luminescent layer 14 in the current non-injection region 63. In this case, the optical waveguide has a structure equivalent to the normal shallow mesa structure, effectively.

Accordingly, it is found that, when the inter-mesa distance d is determined appropriately, the second light 72 is coupled into the mode of the optical waveguide while suppressing the effect of non-radiative recombination in the side surface of the second mesa portion 32, and thus the rising current of the SLD can be reduced.

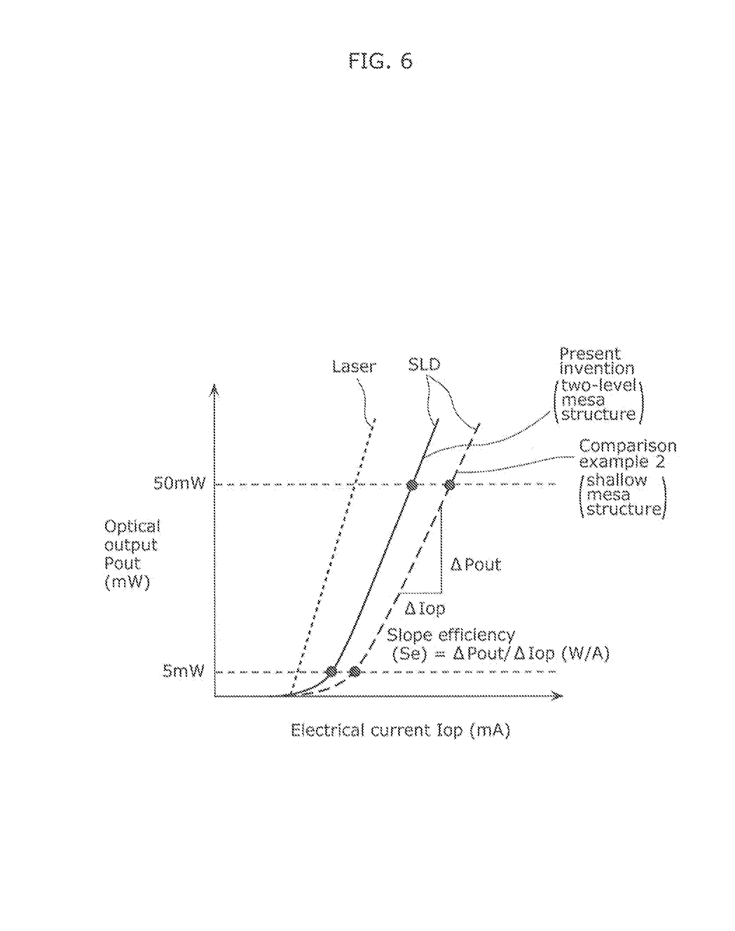

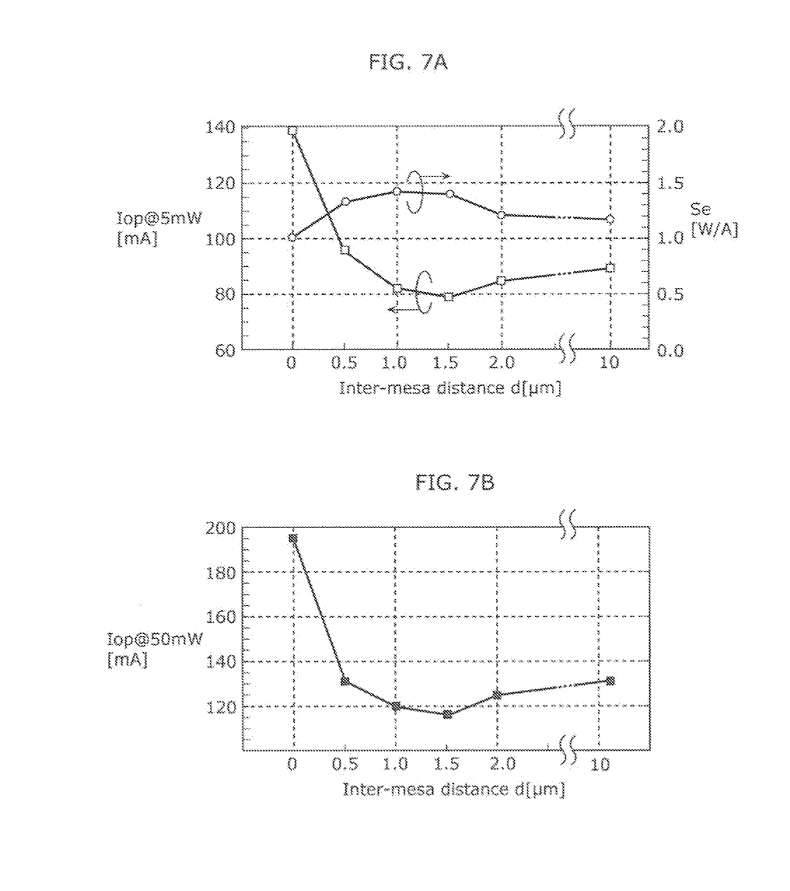

The following describes a relationship between the characteristics of the SLD device and the inter-mesa distance d with reference to FIG. 6, FIG. 7A, and FIG. 7B. FIG. 6 illustrates a graph showing electrical current vs. optical output characteristics for three semiconductor light-emitting devices: the SLD according to the embodiment (the present disclosure), the SLD according to the comparison example 1 (comparison example 1), and a LD. Furthermore, FIG. 7A illustrates a graph showing a relationship between the inter-mesa distance d and the rising current (Iop) at the optical output of 5 mW or slope efficiency (Se) for the SLD according to the embodiment. Furthermore, FIG. 7B illustrates a graph showing a relationship between the inter-mesa distance d and the operating current (Iop) at the optical output of 50 mW for the SLD according to the embodiment. In FIG. 7A and FIG. 7B, it is assumed that the first mesa portion 31 has a ridge width W1 of 1.5 μm and the inter-mesa distance d is a distance from a ridge side surface of the first mesa portion 31. Furthermore, the optical waveguide has a length L of 800 μm.

As shown in FIG. 6, the SLD having the two-level mesa optical waveguide according to the present disclosure has a lower rising current and a higher slope efficiency than those of the SLD having the shallow-mesa optical waveguide according to the comparison example 1. In addition to this, the operating current is also reduced. It should be noted that the slope efficiency (Se) is expressed as the ratio of an amount of change in optical output to an amount of change in current (ΔPout/ΔIop).

It is found that an operational advantage of the SLD according to the embodiment depends on the inter-mesa distance d, and as shown in FIG. 7A and FIG. 7B, the characteristics are improved at an inter-mesa distance d ranging from about 0.5 μm to 2.0 μm, particularly, about 1.5 μm is the best.

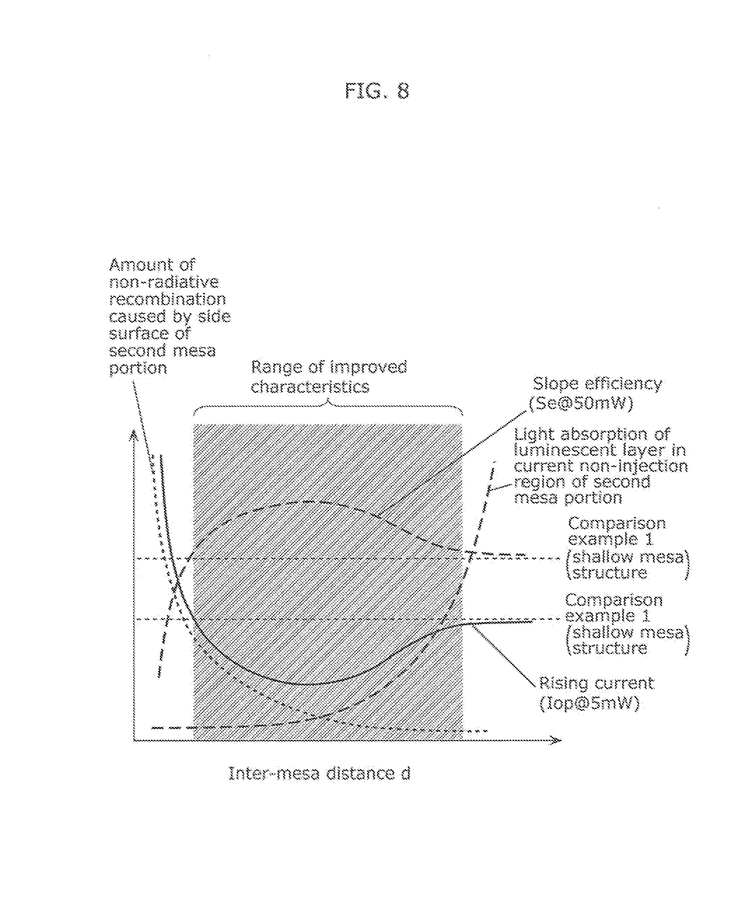

The dependency of the inter-mesa distance is described with reference to FIG. 8. FIG. 8 illustrates a graph schematically showing an effect of the inter-mesa distance in the SLD according to the embodiment.

As shown in FIG. 8, firstly, the number of carriers (electrons and holes) reaching the side surface of the second mesa portion 32 decreases exponentially with increasing the inter-mesa distance d, so that carrier loss caused by the non-radiative recombination at the side surface of the second mesa portion 32 is reduced.

On the other hand, the propagation distance of light increases with increasing the inter-mesa distance d, so that light absorption by the luminescent layer 14 within the current non-injection region 63 of the second mesa portion 32 increases exponentially.

There is a trade-off between the decrease in carrier loss caused by the non-radiative recombination at the side surface of the second mesa portion 32 and the increase in light absorption in the current non-injection region 63. Accordingly, as shown in FIG. 8, it is found that the SLD has improved characteristics only within a predetermined range of the inter-mesa distance d. As described above, the SLD according to the embodiment has improved characteristics within a range of the inter-mesa distance d, from about 0.5 μm to 2.0 μm.

It should be noted that, in the nitride semiconductor SLD according to the embodiment, the carrier loss caused by the non-radiative recombination is large due to the surface damage induced by dry etching, so that the range from 0.5 μm to 2.0 μm is an optimum range of the inter-mesa distance d. However, it is possible to further decrease the lower limit of the optimum range of the inter-mesa distance d by removing a surface damage layer. As a method of removing the surface damage layer, (i) a method of removing the surface damage layer using acid such as sulfuric acid, phosphoric acid, or hydrofluoric acid or (ii) a method of re-growing, on the etched surface and side surface, a nitride semiconductor layer having a thickness raging from several nanometers to several tens of nanometers are used. Such a process can suppress the non-radiative recombination induced by the surface damage, so that a desired current can be achieved even when the inter-mesa distance d decreases to about 0.1 μm. Accordingly, it is possible to further reduce the rising current of the SLD. Thus, for the SLD 100 according to the embodiment, a desired range of the inter-mesa distance d is not less than 0.1 and not more than 2.0.

Next, the characteristics of the semiconductor laser having the mesa optical waveguide are described.

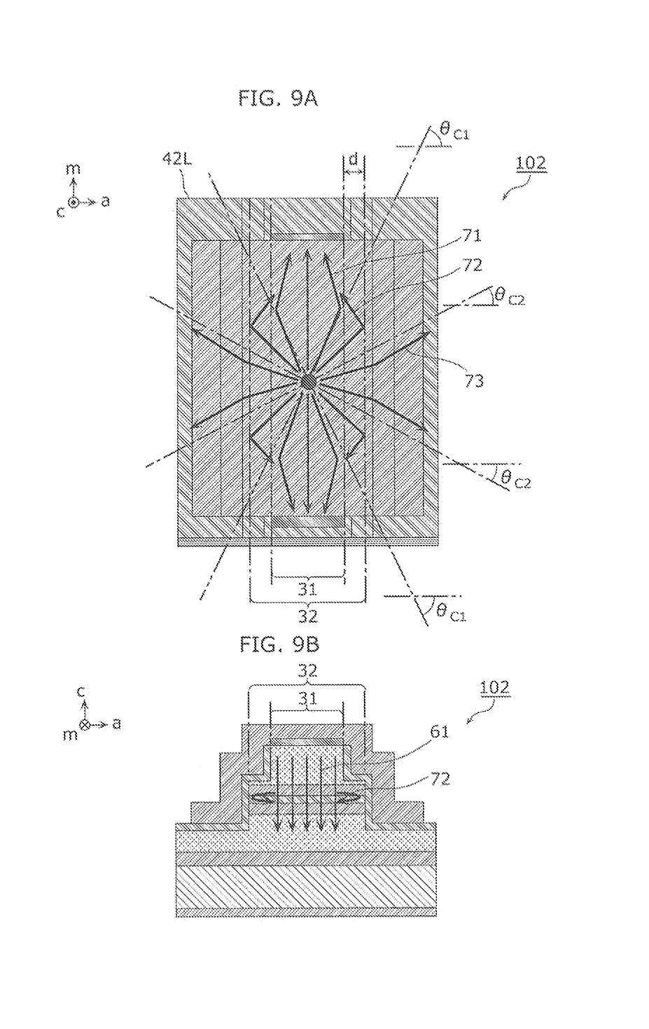

FIG. 9A illustrates a top view of the semiconductor laser having an optical waveguide with the two-level mesa structure similar to that of the SLD according to the embodiment. Furthermore, FIG. 9B illustrates a cross-sectional view of the same semiconductor laser.

As shown in FIG. 9A and FIG. 9B, the semiconductor laser 102 having the two-level mesa optical waveguide has the same structure as the SLD 100 shown in FIG. 1A, FIG. 1B, FIG. 3A, and FIG. 3B except the front end face 42L which is an end face perpendicular to the longitudinally extending axis of the optical waveguide.

Like the SLD 100 shown in FIG. 3A, the second light 72 propagating through the second mesa portion 32 also exists in the semiconductor laser 102 shown in FIG. 9A. However, for the semiconductor laser 102, the second light does not contribute to the improvement in characteristics.

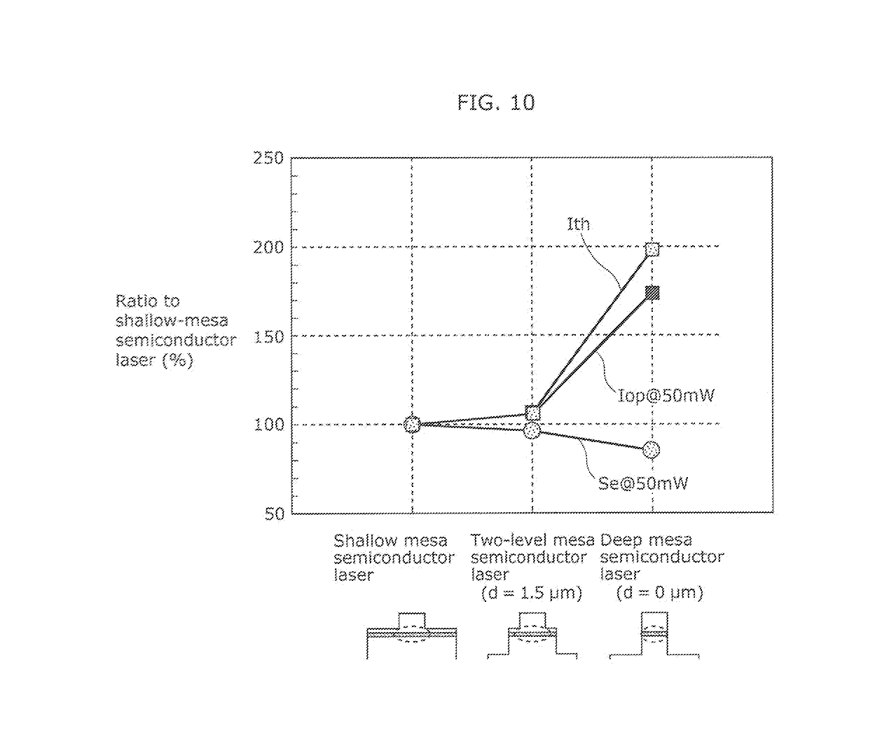

FIG. 10 illustrates a comparison graph showing the threshold current Ith, the slope efficiency Se (at the optical output of 50 mW), and the operating current lop (at the optical output of 50 mW) for three nitride semiconductor lasers: a laser having a shallow-mesa optical waveguide, a laser having a two-level mesa optical waveguide, and a laser having a deep-mesa optical waveguide. In FIG. 10, the values of the threshold Ith, the slope efficiency Se, and the operating current are expressed relative to the values of the threshold Ith, the slope efficiency Se, and the operating current of the nitride semiconductor laser having the shallow-mesa optical waveguide, respectively.

This graph shows that the nitride semiconductor laser having the deep-mesa optical waveguide has a threshold current and an operating current larger than those of the other nitride semiconductor lasers due to the non-radiative recombination in the deep mesa portion, and the characteristics are degraded. Furthermore, the characteristics are not improved for the nitride semiconductor laser having the two-level mesa optical waveguide. This is because the semiconductor laser uses oscillation phenomenon in the optical resonator, so that the threshold current and the slope efficiency are almost unaffected by the spontaneously-emitted-light coupling factor A.

On the other hand, in the SLD, the oscillation phenomenon does not occur. Spontaneously emitted light acts as a seed of light, and this seed of light is amplified in the optical waveguide while propagating through the optical waveguide. Accordingly, it is very important for the improvement in characteristics that the spontaneously-emitted-light coupling factor A, which is also a use efficiency of the seed of light, is large.

Thus, the semiconductor laser differs in principle of operation from the SLD. Accordingly, even when the two-level mesa optical waveguide is applied to the semiconductor laser, there is no effect. The improvement in characteristics due to the two-level mesa structure is specific to the SLD.

As described above, the SLD 100 according to the embodiment 1 has the two-level mesa optical waveguide including the first mesa portion 31 and the second mesa portion 32, and thus the spontaneously-emitted-light coupling factor A can be increased while suppressing the effect of non-radiative recombination in the second mesa portion 32. With this, the rising current is reduced and the slope efficiency is improved. Accordingly, it is possible to make the SLD having the high directivity, the high polarizability, and the low coherence more efficient.

Furthermore, the SLD according to the embodiment has an inter-mesa distance d ranging from 0.1 to 2.0 inclusive, and thus the light absorption loss in the luminescent layer can be suppressed while suppressing the effect of non-radiative recombination. With this, the effective spontaneously-emitted-light coupling factor can be increased within the optimum range.

Furthermore, in the embodiment, the longitudinally extending axis of the linear optical waveguide 21 is parallel to the side surface 53 of the SLD 100. Moreover, the optical waveguide 21 has the front end face 42 whose normal is tilted relative to the longitudinally extending axis of the optical waveguide 21, and the rear end face 43 whose normal is parallel to the longitudinally extending axis of the optical waveguide 21. With this, a uni-face output SLD having the front end face 42 which is a tilted light output end face and the rear end face 43 which is a reflective end face can be easily achieved through the use of only the linear optical waveguide with a low waveguide loss.

### (Variation 1 of Embodiment 1)

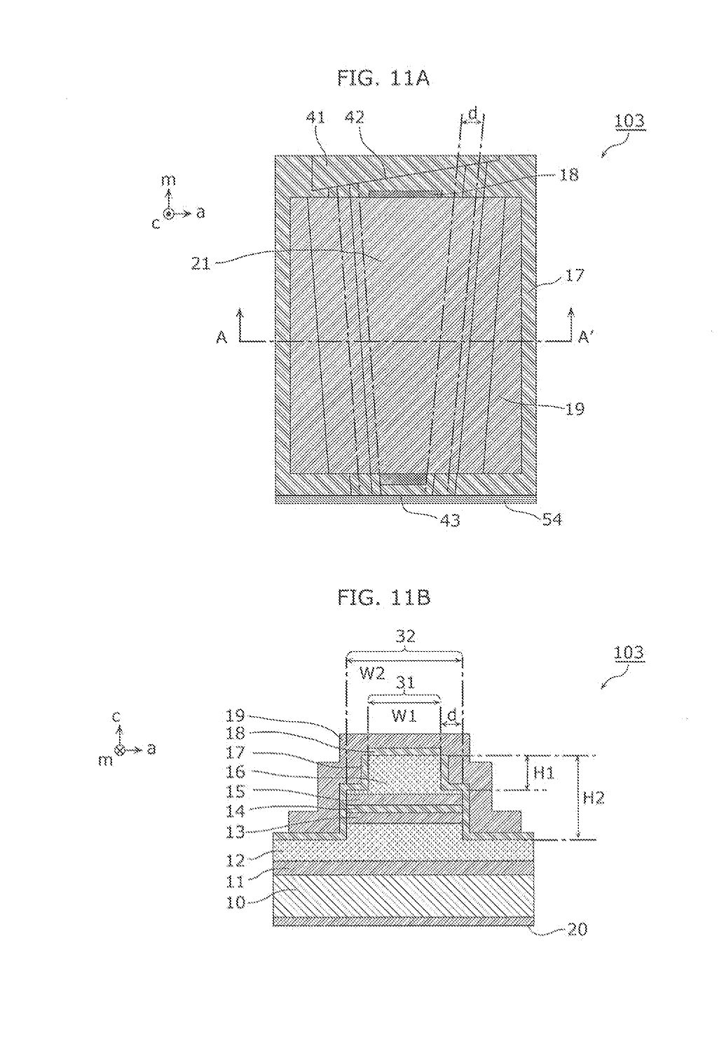

Next, a SLD 103 according to a variation 1 of the embodiment 1 is described with reference to FIG. 11A and FIG. 11B. FIG. 11A is a top view of the SLD according to the variation 1 of the embodiment 1. FIG. 11B is a cross-sectional view of the SLD according to the same variation 1 along the line A-A′ shown in FIG. 11A.

The SLD 100 according to the embodiment 1 shown in FIG. 1A has an optical waveguide 21 having a constant width ranging from about 1.0 μm to 2.0 μm. However, as shown in FIG. 11A, in the SLD 103 according to the variation, a ridge width W1 of a first mesa portion 31 and a ridge width W2 of a second mesa portion 32 vary gradually in a direction of light propagation through an optical waveguide 21C. In this variation, the optical waveguide 21C has a tapered shape having the ridge widths W1 and W2 gradually widened from the rear end face 43 toward the front end face 42.

With this, an area of the luminescent layer 14 can be increased, and thus the amplification effect in the optical waveguide 21C also can be increased.

Here, it is desirable that the inter-mesa distance d be constant even when the width of the optical waveguide 21C varies, as shown in the variation. It is found that the optimum inter-mesa distance d in this variation is almost the same as that of the embodiment 1.

### (Variation 2 of Embodiment 1)

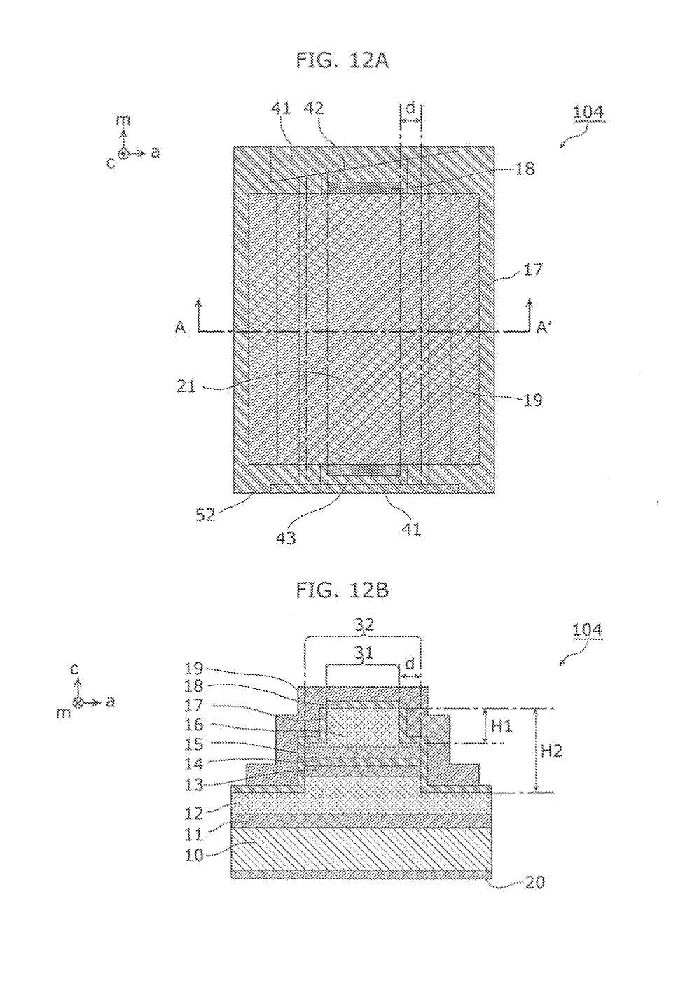

Next, a SLD 104 according to a variation 2 of the embodiment 1 is described with reference to FIG. 12A and FIG. 12B. FIG. 12A is a top view of the SLD according to the variation 2 of the embodiment 1. FIG. 12B is a cross-sectional view of the SLD according to the same variation 2 along the line A-A′ shown in FIG. 12A.

As shown in FIG. 1A, the SLD 100 according to the embodiment 1 has the rear end face 43 formed by cleavage. However, as shown in FIG. 12A, in the SLD 104 according to the variation, the rear end face 43 is formed by forming an end recess 41, like the front end face 42. In this case, the end recess 41 is created in the rear face 52 so as to form the rear end face 43 which is an end face perpendicular to the longitudinally extending axis of the optical waveguide 21.

With this, the devices can be separated by scribing the wafer instead of cleaving, and thus it is possible to manufacture the SLDs at lower cost.

It should be noted that a non-reflective layer or a low reflectivity layer including a dielectric single-layer film or a dielectric multilayer film can be formed on the front end face 42. On the other hand, a high reflectivity layer including the dielectric multilayer film can be formed on the rear end face 43.

### Embodiment 2

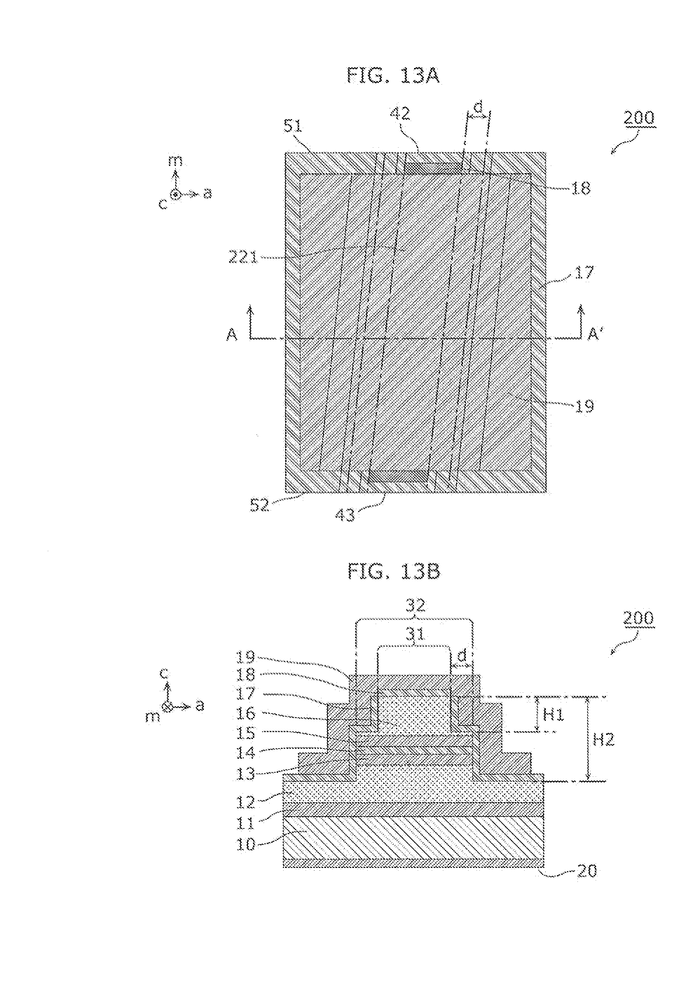

Next, a SLD 200 according to an embodiment 2 is described with reference to FIG. 13A and FIG. 13B. FIG. 13A is a top view of the SLD according to the embodiment 2. FIG. 13B is a cross-sectional view of the SLD according to the same embodiment along the line A-A′ shown in FIG. 13A.

The SLD 200 according to the embodiment 2 is a nitride semiconductor blue SLD device and has an optical waveguide 221 tilted relative to the forward face 51 and the rear face 52 as shown in FIG. 13A. In the embodiment, the normal to the front end face 42 of the linear optical waveguide 221 and the normal to the rear end face of the linear optical waveguide 221 are tilted relative to the longitudinally extending axis (an axis in a stripe direction) of the optical waveguide 221. It should be noted that the SLD according to the embodiment 2 basically has the same structure as the SLD according to the embodiment 1 except the optical waveguide 221 which is tilted relative to the forward face 51 and the rear face 52.

With this, the front end face 42 or the rear end face 43 is a tilted end face, and thus the end recess need not be formed. Accordingly, the SLD having the light output end face formed as the tilted end face can be easily manufactured only by cleaving. In other words, in the embodiment 2, the front end face 42 and the rear end face 43 which are the tilted end faces can be formed by cleaving.

Furthermore, in the embodiment, light propagating through the optical waveguide 221 exits from both the front end face 42 and the rear end face 43. Accordingly, the highly-efficient SLD can be achieved by mounting the SLD in a package in which light from the both end faces is available.

As described above, the SLD 200 according to the embodiment 2 can be simplified to achieve low cost and also made more efficient, compared to the SLD according to the embodiment 1.

It should be noted that the SLD 200 according to the embodiment is a bi-face output SLD including the rear end face 43 which is also the light output end face, and light exits from both the front end face 42 and the rear end face 43. Accordingly, it is desirable that the low reflectivity layer including the dielectric single-layer film or the dielectric multilayer film is formed not only on the front end face 42 but also on the rear end face 43. With this, the reflectivity of the front end face 42 and the reflectivity of the rear end face 43 are minimized, and thus a more highly-efficient SLD can be achieved.

### Embodiment 3

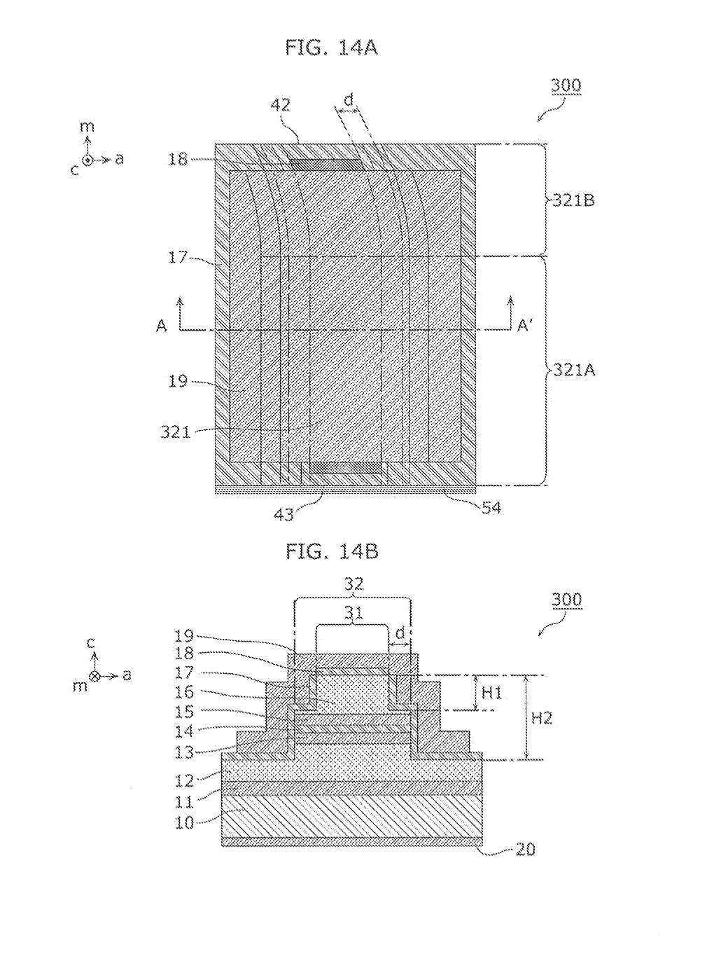

Next, a SLD 300 according to an embodiment 3 is described with reference to FIG. 14A and FIG. 14B. FIG. 14A is a top view of the SLD according to the embodiment 3. FIG. 14B is a cross-sectional view of the SLD according to the same embodiment along the line A-A′ shown in FIG. 14A.

The SLD 300 according to the embodiment 3 is a nitride semiconductor blue SLD device and has an optical waveguide 321 including a linear waveguide portion 321A having a linear shape and a curved waveguide portion 321B having a curved shape, as shown in FIG. 14A. In the optical waveguide 321, the curved waveguide portion 321B is tilted relative to the front end face 42 and the linear waveguide portion 321A is perpendicular to the rear end face 43. It should be noted that the SLD according to the embodiment has the same structure as the SLD according to the embodiment 1 except the curved waveguide portion 321B which is a part of the optical waveguide 321.

With this, the SLD having the optical waveguide 321 which is tilted relative to the front end face 42 formed by cleaving instead of creating an end recess can be achieved. Furthermore, the dielectric multilayer film 54, which is the high reflectivity layer, is formed on the rear end face 43, and thus a more highly-efficient SLD with a structure in which light exits only from the front end face 42 can be achieved.

Here, it is desirable that the radius of curvature of the arc portion be as large as possible because waveguide loss occurs in the curved waveguide portion 321B due to the curve of the arc portion.

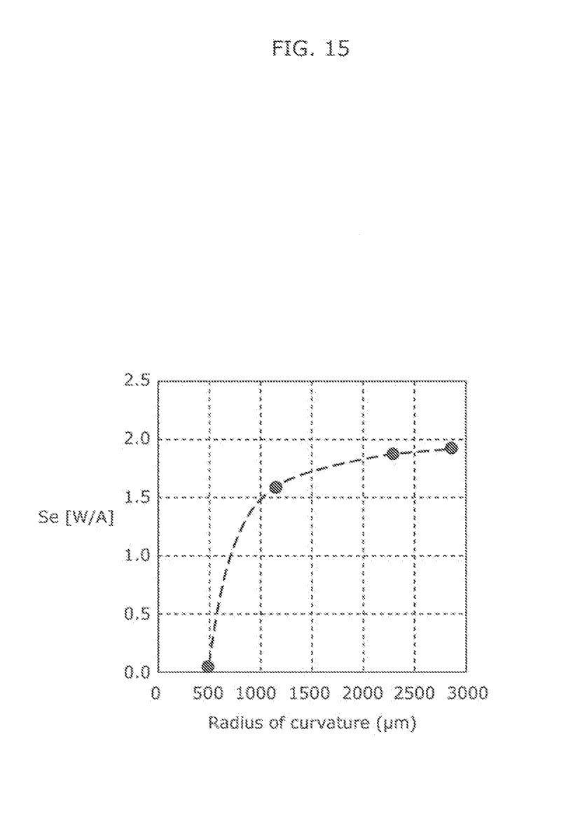

Referring to FIG. 15, the following describes a relationship between the slope efficiency and the radius of curvature of the arc portion in the curved waveguide portion 321B of the optical waveguide 321. FIG. 15 illustrates a graph showing the relationship between the slope efficiency and the radius of curvature of the arc portion in the curved waveguide portion 321B for the SLD 300 according to the embodiment 3. As shown in FIG. 15, for the nitride semiconductor blue SLD, the desired radius of curvature of the arc portion in the curved waveguide portion 321B is more than or equal to 1000 μm.

It should be noted that the SLD according to the embodiment has the curved waveguide portion 321B formed in the front-end-face 42 side of the optical waveguide 321, but the curved waveguide portion 321B may be formed in the middle or the rear-end-face 43 side of the optical waveguide 321.

As described above, since the optical waveguide 321 includes the linear waveguide portion 321A and the curved waveguide portion 321B, the SLD 300 according to the embodiment 3 can be simplified to achieve low cost and also made more efficient, compared to the SLD according to the embodiment 1. Furthermore, a uni-face output SLD having the front end face 42 which is a tilted light output end face and the rear end face 43 which is a reflective end face can be easily achieved.

### Embodiment 4

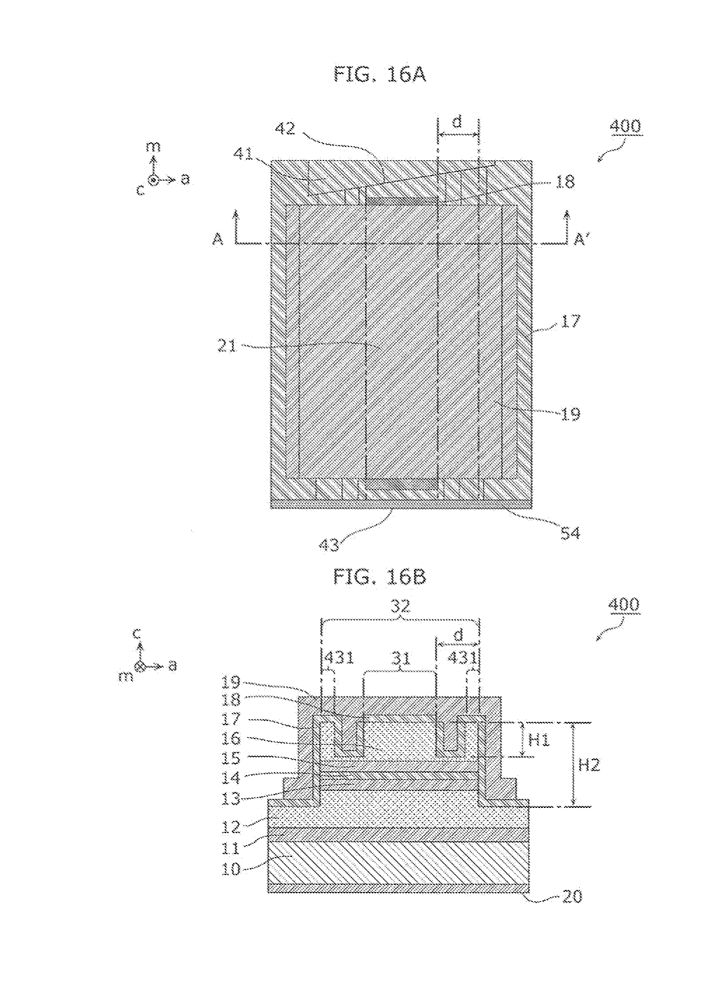

Next, a SLD 400 according to an embodiment 4 is described with reference to FIG. 16A and FIG. 16B. FIG. 16A is a top view of the SLD according to the embodiment 4. FIG. 16B is a cross-sectional view of the SLD according to the same embodiment along the line A-A′ shown in FIG. 16A.

The SLD 400 according to the embodiment 4 is a nitride semiconductor blue SLD device which includes protrusions 431 each having a height equal to that of a first mesa portion 31 and formed as a part of a second mesa portion 32, as shown in FIG. 16B.

The protrusion 431 is formed away from the first mesa portion 31 and above a current non-injection region of the second mesa portion 32 by processing an upper cladding layer 16. A recess is formed between the first mesa portion 31 and the protrusion 431, thereby forming the first mesa portion 31 and the protrusion 431 with the recess provided therebetween to separate from each other. In other words, when the first mesa portion 31 is formed, the structure according to the embodiment can be achieved in a manner in which the protrusion 431 does not removed in an etching process.

For a deep mesa structure such as the second mesa portion 32, an etched surface or a side surface of a deep mesa portion is damaged by dry-etching during a mesa forming process, so that the top surface exposed by dry-etching is easy to change to n-type. Accordingly, in the deep mesa structure, the side surface of the mesa portion is formed by passing through a p-n junction interface including a luminescent layer 14, and thus the surface damage induced by dry etching often causes surface leakage current.

In contrast, in the embodiment, the top surface of the protrusion 431 is a non-etched surface which is not dry-etched, and thus a p-type surface exists as the non-etched surface in a part of the protrusion 431. With this, n-p-n junction is formed along a path from the p-side electrode 18 to the n-type semiconductor layer via the side surface of the first mesa portion 31, the side surface of the protrusion 431, the top surface of the protrusion 431, and the side surface of the second mesa portion 32. With this, there is no leakage path, and thus the surface leakage current can be suppressed.

As described above, the SLD 400 according to the embodiment 4 can reduce the surface leakage current. Accordingly, a highly-reliable SLD can be achieved.

### Embodiment 5

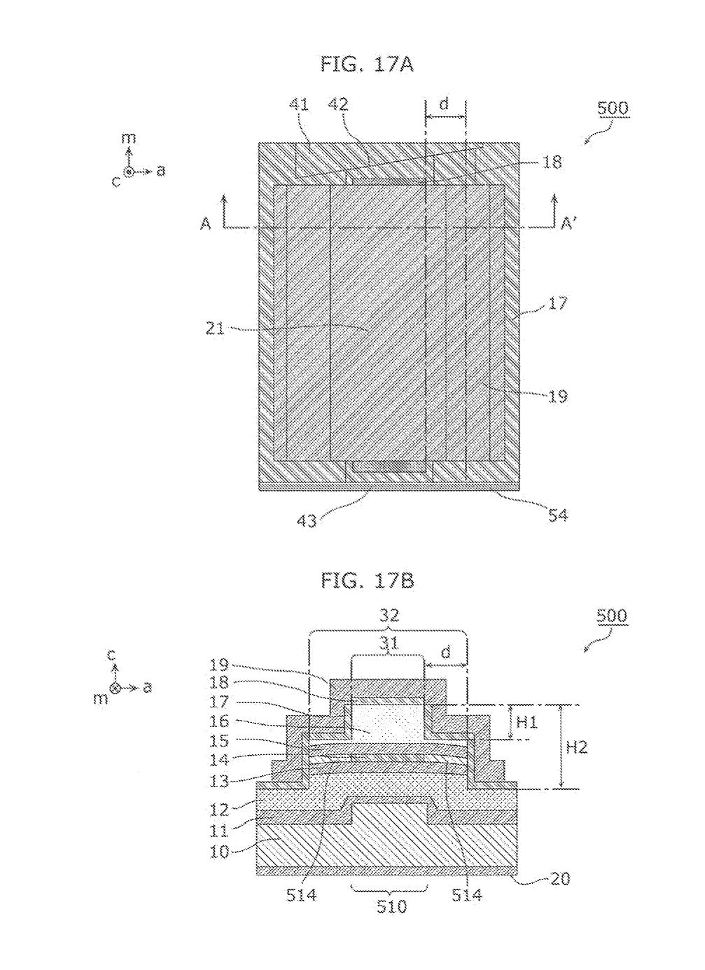

Next, a SLD 500 according to an embodiment 5 is described with reference to FIG. 17A and FIG. 17B. FIG. 17A is a top view of the SLD according to the embodiment 5. FIG. 17B is a cross-sectional view of the SLD according to the same embodiment along the line A-A′ shown in FIG. 17A.

The SLD 500 according to the embodiment 5 is a nitride semiconductor blue SLD device in which a semiconductor layered portion including a luminescent layer 14 is formed above a substrate 10 having a protrusion 510, as shown in FIG. 17B. An optical waveguide 21 including a first mesa portion 31 and a second mesa portion 32 is formed above the protrusion 510, and a second portion of the luminescent layer 14 located between the side surface of the first mesa portion 31 and the side surface of the second mesa portion 32 (a current non-injection region) has a bandgap larger than that of a first portion of the luminescent layer 14 located under the first mesa portion 31 (a current injection region). In other words, the first portion of the luminescent layer 14 located under the first mesa portion 31 has the bandgap smaller than that of the second portion of the luminescent layer 14 located in the second mesa portion 32 between the side surface of the first mesa portion 31 and the side surface of the second mesa portion 32. Thus, in the embodiment, the second portion of the luminescent layer 14 in the second mesa portion 32 located between the side surface of the first mesa portion 31 and the side surface of the second mesa portion 32 is a bandgap increase region 514 where the bandgap is increased.

For example, the semiconductor layered portion including the luminescent layer 14 is grown on the substrate 10 where the protrusion 510 is formed in advance, and then the first mesa portion 31 and the second mesa portion 32 are formed at the position of the protrusion 510. With this, the SLD 500 with the structure as shown in FIG. 17B can be manufactured.

It should be noted that, in the forming process of the buffer layer 11 and the lower cladding layer 12, the growth conditions are changed so that their layer surfaces are sloped mildly in the area adjacent to the protrusion 510 of the substrate 10. When the luminescent layer 14 is grown on the sloped layer surface, due to the angle of slope of the growth surface, a region with a different adsorbability of indium (In) onto the surface is formed. In other words, an upper portion located right over the protrusion 510 differs in efficiency of absorbing In from an adjacent portion adjacent to the upper portion, and thus the luminescent layer 14 in the upper portion has an In composition lower than that of the adjacent portion. With this, the bandgap increase region 514 can be formed as the region where the bandgap is increased.

The second light 72 (not shown) propagates through the bandgap increase region 514. Accordingly, light is not absorbed between the first mesa portion 31 and the second mesa portion 32, thereby maximizing the spontaneously-emitted-light coupling factor A. With this, a highly-efficient SLD can be achieved. Thus, in the embodiment, light is not absorbed between the first mesa portion 31 and the second mesa portion 32. Accordingly, the spontaneously-emitted-light coupling factor A can be increased to almost the same value as that of the deep mesa structure, and the inter-mesa distance d can be also increased beyond that of the embodiment 1. For example, it is possible to increase the inter-mesa distance d up to about 10 μm.

As described above, the SLD 500 according to the embodiment 5 can be simplified and made more efficient compared to the SLD according to the embodiment 1.

### Embodiment 6

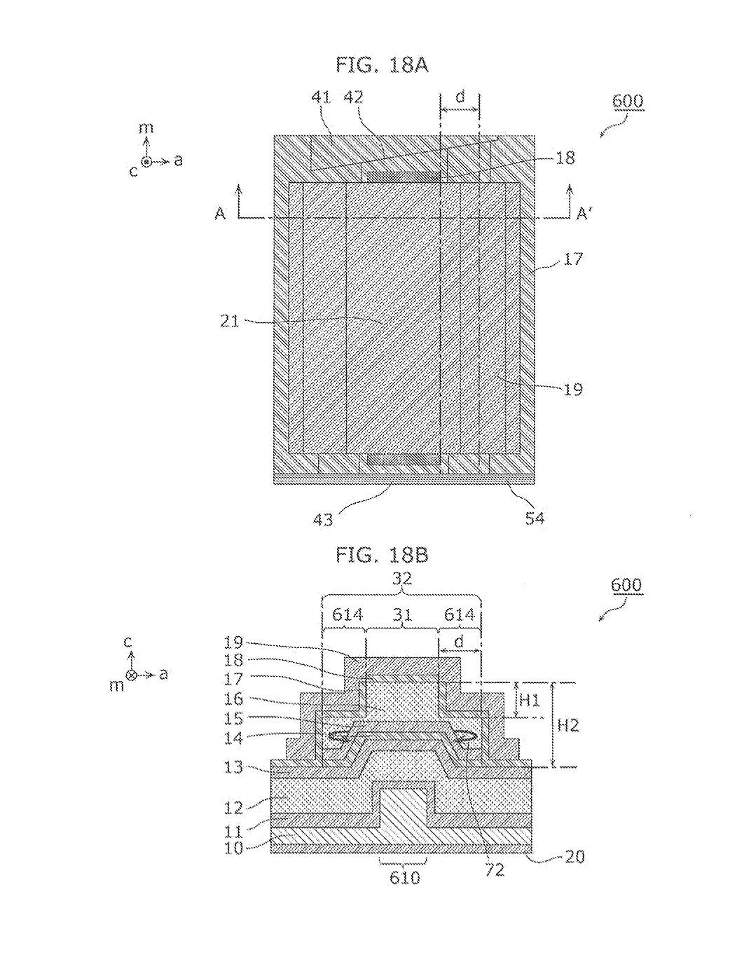

Next, a SLD 600 according to an embodiment 6 is described with reference to FIG. 18A and FIG. 18B. FIG. 18A is a top view of the SLD according to the embodiment 6. FIG. 18B is a cross-sectional view of the SLD according to the same embodiment along the line A-A′ shown in FIG. 18A.

The SLD 600 according to the embodiment 6 is a nitride semiconductor blue SLD device in which a semiconductor layered portion including a luminescent layer 14 is formed above a substrate 10 having a protrusion 610, as shown in FIG. 18B. An optical waveguide 21 including a first mesa portion 31 and a second mesa portion 32 is formed above the protrusion 610, and there is a difference in level between a first portion of the luminescent layer 14 located under the first mesa portion 31 (a current injection region) and a second portion of the luminescent layer 14 located between the side surface of the first mesa portion 31 and the side surface of the second mesa portion 32 (a current non-injection region).

For example, in a similar manner to the embodiment 5, the semiconductor layered portion including the luminescent layer 14 is grown on the substrate 10 where the protrusion 610 is formed in advance, and then the first mesa portion 31 and the second mesa portion 32 are formed at the position of the protrusion 510. With this, the SLD 600 with the structure as shown in FIG. 18B can be manufactured.

However, in the embodiment, the height of the protrusion 610 (step height) is greater than that of the embodiment 5. After this, the luminescent layer 14 is grown while maintaining the step shape of the protrusion 610 by changing the forming conditions of the buffer layer 11 and the lower cladding layer 12. With this, a first portion of the luminescent layer 14 located under the first mesa portion 31 and a second portion of the luminescent layer 14 in the second mesa portion 32 are located at different levels in a stacking direction of the semiconductor layered portion. When the luminescent layer 14 has such a structure, light traveling from the first portion of the luminescent layer 14 through the second mesa portion 32 passes mainly through the upper cladding layer 16. This can prevent the second light 72 from being absorbed into the second portion of the luminescent layer 14 in the second mesa portion 32 located between the side surface of the first mesa portion 31 and the side surface of the second mesa portion 32.

Thus, in the embodiment, the absorption loss of the second light 72 is reduced. Accordingly, the spontaneously-emitted-light coupling factor A can be maximized and a more highly-efficient SLD can be achieved. Furthermore, in the embodiment, the light absorption in the second portion of the luminescent layer 14 decreases, and thus the inter-mesa distance d can be increased beyond that of the embodiment 1. For example, it is possible to increase the inter-mesa distance d up to about 10 μm.

As described above, the SLD 600 according to the embodiment 6 can be made more efficient.

### Embodiment 7

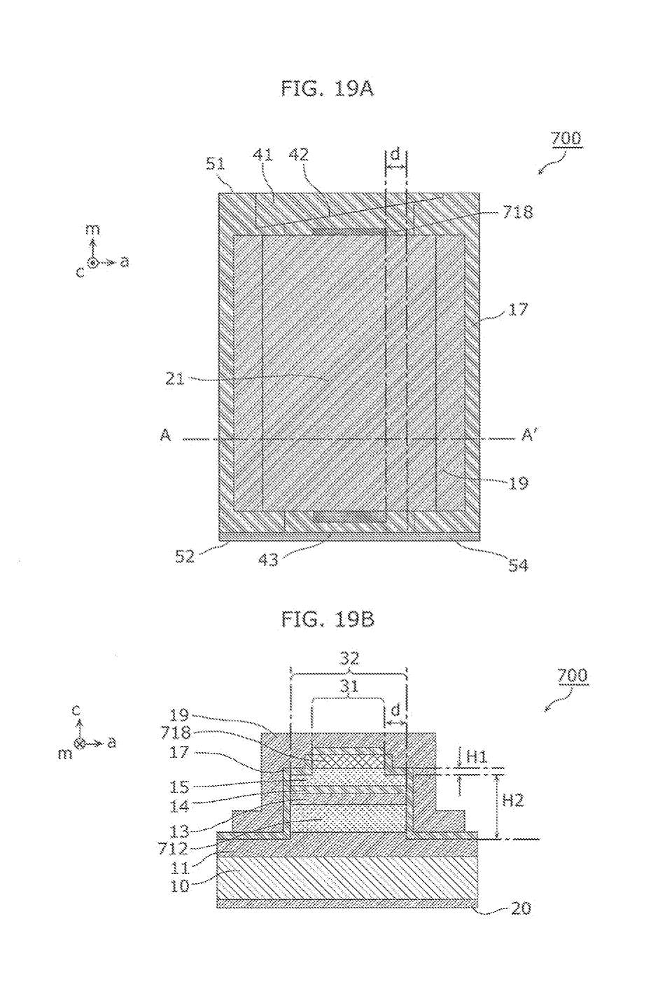

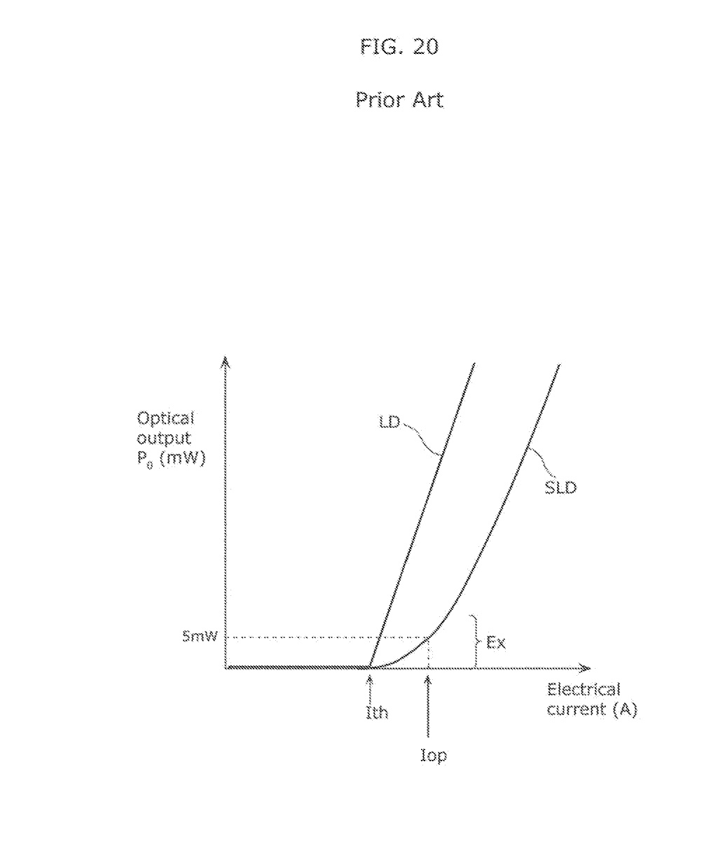

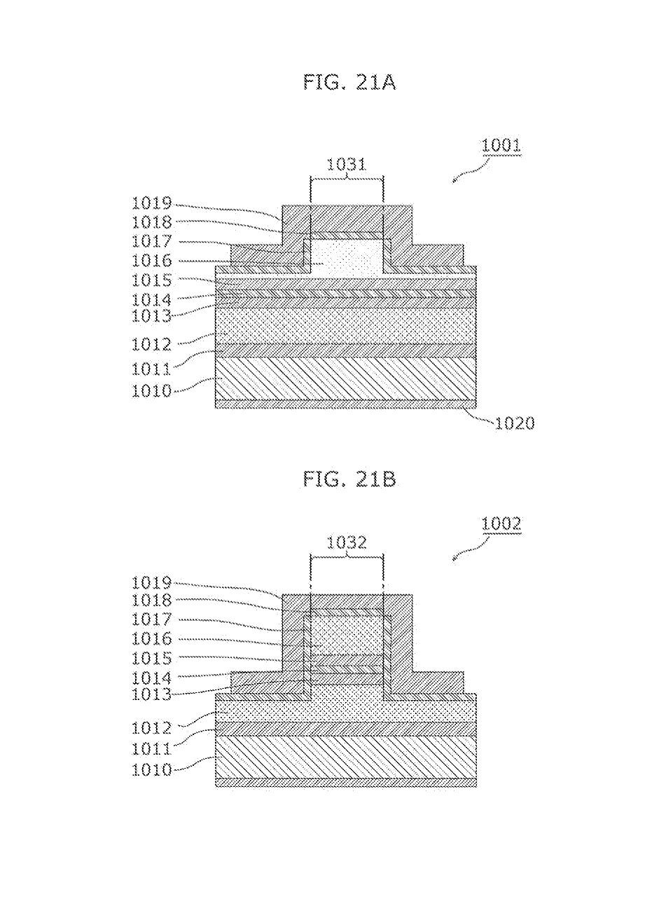

Next, a SLD 700 according to an embodiment 7 is described with reference to FIG. 19A and FIG. 19B. FIG. 19A is a top view of the SLD according to the embodiment 7. FIG. 19B is a cross-sectional view of the SLD according to the same embodiment along the line A-A′ shown in FIG. 19A.

The SLD 700 according to the embodiment 7 includes an n-type lower cladding layer 712 comprising AlInN and a p-side electrode 718 comprising indium tin oxide (ITO). In the SLD 700 according to the embodiment, light is strongly confined in a vertical direction of an optical waveguide using AlInN and ITO which are low refractive index materials, and the efficiency can be further improved in combination with the effect of the increased spontaneously-emitted-light coupling factor A due to the two-level mesa structure. The following describes a specific structure of the SLD 700 according to the embodiment in detail.

As shown in FIG. 19A and FIG. 19B, the SLD 700 according to the embodiment includes a substrate 10 comprising n-type GaN, and a semiconductor layered portion in which a buffer layer 11 comprising n-type GaN, a lower cladding layer 712 comprising n-type AlInN, a lower guiding layer 13, a luminescent layer 14, an upper guiding layer 15, and a contact layer comprising p-type GaN (not shown) are sequentially formed above the substrate 10. It should be noted that a carrier over-flow suppression (OFS) layer comprising p-type AlGaN may be provided as a part of the upper guiding layer 15. Furthermore, a cladding layer comprising p-type AlGaN and having a thickness of about 10 nm to 100 nm may be provided under the contact layer.

In the embodiment, a first mesa portion 31 is formed by processing a part of the upper guiding layer 15 into a stripe mesa structure. In addition, a second mesa portion 32 is formed by digging to the lower cladding layer 712. Thus, the ridge-shaped optical waveguide 21 according to the embodiment is a two-level mesa optical waveguide including the first mesa portion 31 and the second mesa portion 32 having a width greater than that of the first mesa portion 31.

On the upper guiding layer 15, a dielectric insulating layer 17 comprising SiO₂ and having an opening in which a top surface of the first mesa portion 31 is exposed is formed. The p-side electrode 718 comprising ITO is formed on the top surface of the first mesa portion 31 (the upside of the protrusion of the upper cladding layer 15) so as to fill the opening of the dielectric insulating layer 17. Furthermore, the pad electrode 19 electrically connected to the p-side electrode 718 is formed on the p-side electrode 718 and the dielectric insulating layer 17. It should be noted that an n-side electrode 20 is formed on the back surface of the substrate 10.

Furthermore, as shown in FIG. 19A, a front end face 42 is formed by etching a forward face 51 of the SLD device to create an end recess 41. The optical waveguide 21 according to the embodiment is a linear waveguide having a stripe shape, and the longitudinally extending axis of the optical waveguide 21 is tilted relative to the normal to the front end face 42, as shown in FIG. 19A. It should be noted that a rear face 52 is made by forming a dielectric multilayer film 54 on the rear end face 43 perpendicular to the longitudinally extending direction (in a longitudinal direction) of the optical waveguide 21.

Thus, for the SLD 700 according to the embodiment, AlₓIn₁₋ₓN (0<x<1) having a refractive index of 2.4 or less is used as a material of the n-type lower cladding layer 712. AlInN is a material having a very low refractive index. When the In composition is about 17.7%, AlInN is lattice matched to GaN and has the refractive index of about 2.2. This AlInN can be used as the n-type cladding layer to increase a difference in refractive index between AlInN and GaN even in a long wavelength range of 540 nm or more. It should be noted that a desirable structure of the lower cladding layer 712 is a multiple superlattice structure of AlInN and GaN because AlInN has low conductivity. In this case, Si may be doped with an n-type impurity. This doping may be uniform doping or modulation doping in accordance with the period of the superlattice.

Furthermore, the SLD 700 according to the embodiment uses the p-type electrode 718 comprising ITO, as a component acting as the p-type cladding layer. In other words, the p-type electrode 718 comprising ITO acts as not only the upper cladding layer as shown in the other embodiments but also an electrode. ITO is a transparent conductive material having a low refractive index of about 2.0, and is widely used as a transparent electrode in a display device such as a liquid crystal panel, a LED, or the like. When ITO is used as a p-type electrode in a semiconductor laser or a SLD, little light is absorbed unlike the conventional metal electrode. Accordingly, the ITO electrode can also act as the p-type cladding layer, and thus the p-type cladding layer in the semiconductor layer can be omitted.

The following describes operational advantages of the SLD 700 with such a structure according to the embodiment in detail.

Another way to decrease the rising current of the SLD is to increase the vertical optical confinement factor Iv shown in Equation 1. In a semiconductor layered portion including a AlGaN layer and a GaN layer, there is a large lattice mismatch between the AlGaN layer and the GaN layer. When the Al composition in the AlGaN cladding layer is increased, cracks occur in the semiconductor layered portion. Accordingly, the Al composition in the cladding layer cannot be increased beyond a certain level, and thus it is difficult to increase the vertical optical confinement factor Iv to 3.5% (when the luminescent layer has three quantum wells) or more at the wavelength of 400 nm. In addition to this, due to the wavelength dependency of the refractive index, the difference in refractive index decreases with increasing the wavelength, and thus the vertical optical confinement factor Iv decreases. Accordingly, for the SLD having a green wavelength range, a decrease in efficiency is a highly significant problem.

In the embodiment, a cladding layer comprising AlInN and having a low refractive index is used as the n-type cladding layer, and a cladding electrode comprising ITO is used as the component acting as the p-type cladding layer. With this, the structure for vertically confining light can be achieved using the cladding layer comprising AlInN and the cladding electrode comprising ITO, and thus the optical confinement factor Iv can be increased.

Accordingly, more than 4% of light can be confined at the wavelength of 400 nm. As a result, the efficiency of the SLD, for example, the rising current, can be improved. In addition, even at the wavelength of 450 nm or more, more than 3.5% of light can be confined, and thus it is possible to make the SLD more efficient even in the blue to green range.

Furthermore, for the SLD comprising nitride semiconductor, there is a problem that the operating voltage is high due to the high resistivity of the p-type semiconductor layer. However, the SLD 700 according to the embodiment uses the cladding electrode comprising ITO, and thus a total thickness of the p-type layers can be decreased. With this, the effect of the decrease in operating voltage can be also achieved, and thus the power conversion efficiency can be improved.

It should be noted that, in the embodiment, the material of the p-side electrode 718 is ITO having the refractive index of about 2.0, but not limited to this. It is possible to use any other conductive transparent material having the refractive index of 2.5 or less as the material of the p-side electrode 718.

Furthermore, in the embodiment, a desired height H1 of the first mesa portion 31 is 150 nm or less. With this, the first mesa portion is appropriately away from the luminescent layer 14, and thus a desired luminescence can be achieved.

Furthermore, in the embodiment, the lower cladding layer 712 comprising AlInN has the refractive index of 2.4 or less. With this, the vertical optical confinement factor of the optical waveguide 21 Γv can be increased across a wavelength range from blue to green, and thus a highly-efficient blue or green SLD can be achieved.

Furthermore, the structure according to the embodiment introduces the ITO cladding electrode and the AlInN cladding layer. However, even when the structure uses either one of the ITO cladding electrode and AlInN cladding layer and has an equivalent structure to any one of the embodiments 1 to 6 other than that, a certain effect can be obtained, and thus a highly-efficient blue or green SLD can be achieved.

The SLD according to the present disclosure is described in the above embodiments and the above variations, but the present disclosure is not limited to these.

For example, in the above embodiments, a blue (B) SLD light source comprising a Group-III nitride semiconductor represented as AlₓGa_{y}In_{1-x-y}N (where, 0≦x≦1, 0≦y≦1, and 0≦x+y≦1) is used as the material of the semiconductor layered portion, but the material of the semiconductor layered portion is not limited to this.

A SLD which emits light within a wavelength range of about 380 nm to 550 nm, i.e. violet (V) to green (G), can be achieved by changing the composition ratio of AlGaInN.

With this, the SLD can be used as the blue or green light source. Furthermore, the blue SLD can be used as a white light source because white light can be obtained by combining the blue SLD with a yellow phosphor, or green and red phosphors.

Furthermore, when the material of the semiconductor layered portion is replaced with a III-V compound semiconductor represented as AlₓGa_{y}In_{1-x-y}As_{z}P_{1-z} (where 0≦x≦1, 0≦y≦1, 0≦z≦1, and 0≦x+y≦1), a SLD which emits light within a wavelength range of about 600 nm to 750 nm, i.e. red (R) to infrared (IR), can be achieved

With this, particularly, a red (R) SLD device, a green (G) SLD device, and a blue (B) SLD device which make a white light source together can be used as highly-color-reproducible light sources for various electrical apparatuses such as a SLD display, a color-filter-less liquid crystal display device with RGB backlight, and a projector.

Various modifications to the embodiment that can be conceived by those skilled in the art as well as forms configured by combining constituent elements in different embodiments which are within the teachings of the present disclosure are included in the scope of the present disclosure.

### INDUSTRIAL APPLICABILITY

A superluminescent diode according to the present disclosure is highly efficient, and thus can be widely used as a thin, low-power, and low-cost light source or the like. In view of this, the superluminescent diode is useful for a backlight source for an ultra-thin liquid crystal display device, a light source for a projector, or the like.

1. A superluminescent diode having, above a substrate, a layered portion including at least a first cladding layer, a luminescent layer, and a second cladding layer in this order, the superluminescent diode comprising
an optical waveguide provided in the layered portion, the optical waveguide having a refractive-index guiding structure,
wherein the optical waveguide includes:
a first mesa portion formed by processing the second cladding layer into the first mesa portion having a first width; and
a second mesa portion formed by processing the first cladding layer, the luminescent layer, and the second cladding layer into the second mesa portion having a second width greater than the first width.

2. The superluminescent diode according to claim 1,
wherein a distance between a side surface of the first mesa portion and a side surface of the second mesa portion ranges from 0.1 μm to 2.0 μm.

3. The superluminescent diode according to claim 1,
wherein a distance between a side surface of the first mesa portion and a side surface of the second mesa portion is constant throughout the optical waveguide.

4. The superluminescent diode according to claim 1,
wherein the first width and the second width vary gradually in a direction of light propagation through the optical waveguide.

5. The superluminescent diode according to claim 1,
wherein the optical waveguide is linear, and
the optical waveguide has a front end face and a rear end face whose normals are tilted relative to a longitudinally extending axis of the optical waveguide.

6. The superluminescent diode according to claim 1,
wherein the optical waveguide is linear,
the optical waveguide has a front end face whose normal is tilted relative to a longitudinally extending axis of the optical waveguide, and
the optical waveguide has a rear end face whose normal is parallel to the longitudinally extending axis of the optical waveguide.

7. The superluminescent diode according to claim 1,
wherein the optical waveguide includes a linear waveguide portion and a curved waveguide portion,
the curved waveguide portion has an end face that is a front end face of the optical waveguide, and
the linear waveguide portion has an end face that is a rear end face of the optical waveguide.

8. The superluminescent diode according to claim 7,
wherein the curved waveguide portion has a radius of curvature of 1000 μm or more.

9. The superluminescent diode according to claim 6,
wherein a high reflectivity layer including a dielectric multilayer film is formed on the rear end face.

10. The superluminescent diode according to claim 6,
wherein a low reflectivity layer including a dielectric single-layer film or a dielectric multilayer film is formed on the front end face.

11. The superluminescent diode according to claim 5,
wherein a low reflectivity layer including a dielectric single-layer film or a dielectric multilayer film is formed on each of the front end face and the rear end face.

12. The superluminescent diode according to claim 1,
wherein the second mesa portion has a protrusion spaced apart from the first mesa portion.

13. The superluminescent diode according to claim 1,
wherein a first portion of the luminescent layer located under the first mesa portion has a bandgap smaller than a bandgap of a second portion of the luminescent layer in the second mesa portion located between a side surface of the first mesa portion and a side surface of the second mesa portion.

14. The superluminescent diode according to claim 1,
wherein a first portion of the luminescent layer located under the first mesa portion and a second portion of the luminescent layer in the second mesa portion are located at different levels in a stacking direction of the layered portion.

15. The superluminescent diode according to claim 1,
wherein the layered portion comprises a III-nitride semiconductor represented as AlₓGa_{y}In_{1-x-y}N, where 0≦x≦1, 0≦y≦1, and 0≦x+y≦1.

16. The superluminescent diode according to claim 1,
wherein the layered portion comprises a III-V compound semiconductor represented as AlₓGa_{y}In_{1-x-y}As_{z}P_{1-z}, where 0≦x≦1, 0≦y≦1, 0≦z≦1, and 0≦x+y≦1.

17. The superluminescent diode according to claim 1,
wherein the second cladding layer comprises a conductive transparent material having a refractive index of 2.5 or less, and
the conductive transparent material also acts as an electrode.

18. The superluminescent diode according to claim 17,
wherein the first mesa portion has a height of 150 nm or less.

19. The superluminescent diode according to claim 17,
wherein the first cladding layer comprises AlₓIn₁₋ₓN, where 0<x<1, and
the first cladding layer has a refractive index of 2.4 or less.
